(19) United States
(12) Patent Application Publication
(10) Pub. No.: US 2015/0076472 A1
(43) Pub. Date: Mar. 19, 2015

(54) LIGHT-EMITTING DEVICE, LIGHTING DEVICE, AND DISPLAY DEVICE

(71) Applicant: SEMICONDUCTOR ENERGY LABORATORY CO., LTD., Atsugi-shi (JP)

(72) Inventors: Shunpei YAMAZAKI, Tokyo (JP); Shinpei MATSUDA, Atsugi (JP); Takuya KAWATA, Atsugi (JP)

(21) Appl. No.: 14/476,771

(22) Filed: Sep. 4, 2014

(30) Foreign Application Priority Data
Sep. 13, 2013 (JP) 2013-190321

(51) Int. Cl. H01L 27/32

(52) U.S. Cl. CPC H01L 27/326
USPC 257/40

(57) ABSTRACT

A light-emitting device, a lighting device, a display device, or the like in which the state of a back surface side can be observed when light is not emitted is provided. The light-emitting device includes a plurality of light-emitting portions and a region transmitting visible light in a region other than the light-emitting portions. Alternatively, the light-emitting device includes a plurality of light-transmitting portions transmitting visible light and a light-emitting portion that can emit light in a region other than the light-transmitting portions. When light is not emitted, the state of a back surface side of the light-emitting device is visible through the region transmitting visible light. When light is emitted, the state of the back surface side of the light-emitting device can be made less visible by diffusion of light emitted from the light-emitting portion.

### BACKGROUND OF THE INVENTION

1. Field of the Invention

One embodiment of the present invention relates to an object, a method, or a manufacturing method. In addition, one embodiment of the present invention relates to a process, a machine, manufacture, or a composition of matter. One embodiment of the present invention relates to a semiconductor device, a light-emitting device, an electronic device, a lighting device, a manufacturing method thereof, or a driving method thereof. In particular, one embodiment of the present invention relates to a light-emitting device, a display device, and an electronic device that utilize an organic electroluminescence (hereinafter also referred to as EL) phenomenon, and a driving method thereof.

In this specification and the like, a semiconductor device generally means a device that can function by utilizing semiconductor characteristics. For example, an electro-optical device, a light-emitting device, a lighting device, a display device, a semiconductor circuit, a transistor, and an electronic device may include a semiconductor device.

2. Description of the Related Art

Research and development have been extensively conducted on light-emitting elements using organic electroluminescence (EL) (also referred to as organic EL elements). In a basic structure of an organic EL element, a layer containing a light-emitting organic compound (also referred to as an EL layer) is provided between a pair of electrodes. By applying voltage to this element, light emission from the light-emitting organic compound can be obtained.

The organic EL element can be formed into a film shape and thus a large-area element can easily be formed. Therefore, utility value of the organic EL element as a surface light source that can be applied to lighting or the like is also high.

For example, Patent Document 1 discloses a lighting device including an organic EL element.

### REFERENCE

### Patent Document

### [Patent Document 1] Japanese Published Patent Application No. 2009-130132

### SUMMARY OF THE INVENTION

One object of one embodiment of the present invention is to provide a light-emitting device, a lighting device, a display device, or the like which is novel. Another object of one embodiment of the present invention is to provide a light-emitting device, a lighting device, a display device, or the like in which the state of a back surface side can be observed when light is not emitted. Another object of one embodiment of the present invention is to provide a light-emitting device, lighting device, display device, or the like which is highly reliable. Another object of one embodiment of the present invention is to provide a light-emitting device, a lighting device, a display device, or the like having low power consumption. Another object of one embodiment of the present invention is to reduce the size or weight of a light-emitting device, a lighting device, a display device, or the like.

Note that the descriptions of these objects do not disturb the existence of other objects. In one embodiment of the present invention, there is no need to achieve all the objects. Other objects will be apparent from and can be derived from the description of the specification, the drawings, the claims, and the like.

According to one embodiment of the present invention, a light-emitting device includes a plurality of light-emitting portions and a region transmitting visible light in a region other than the light-emitting portions. Alternatively, according to one embodiment of the present invention, a light-emitting device includes a plurality of light-transmitting portions transmitting visible light and a light-emitting portion that can emit light in a region other than the light-transmitting portions. When light is not emitted, the state of a back surface side of the light-emitting device can be observed through the region transmitting visible light. When light is emitted, the state of the back surface side of the light-emitting device can be made not to be observed by diffusion of light emitted from the light-emitting portion.

One embodiment of the present invention is a light-emitting device including a light-emitting portion and a plurality of light-transmitting portions. The light-emitting portion is formed to have a net-like shape, and light from a back surface is visible through the light-transmitting portions.

Another embodiment of the present invention is a light-emitting device including a light-transmitting portion and a plurality of light-emitting portions. The plurality of light-emitting portions are arranged in a matrix, and light from a back surface is visible through the light-transmitting portion.

Another embodiment of the present invention is a lighting device or a display device including the above-described light-emitting device.

According to one embodiment of the present invention, a light-emitting device, a lighting device, a display device, or the like in which the state of a back surface side can be observed when light is not emitted can be provided.

According to one embodiment of the present invention, a light-emitting device, a lighting device, a display device, or the like which is novel can be provided.

Note that the description of these effects does not disturb the existence of other effects. In one embodiment of the present invention, there is no need to obtain all the effects. Other effects will be apparent from and can be derived from the description of the specification, the drawings, the claims, and the like.

### BRIEF DESCRIPTION OF THE DRAWINGS

FIGS. 1A and 1B illustrate one embodiment of a light-emitting device.

FIGS. 2A to 2F illustrate an example of a method for manufacturing a light-emitting device.

FIGS. 3A and 3B each illustrate one embodiment of a light-emitting device.

FIGS. 4A and 4B each illustrate one embodiment of a light-emitting device.

FIGS. 5A and 5B illustrate one embodiment of a light-emitting device.

FIGS. 6A to 6E illustrate an example of a method for manufacturing a light-emitting device.

FIGS. 7A and 7B each illustrate one embodiment of a light-emitting device.

FIGS. 8A and 8B each illustrate one embodiment of a light-emitting device.

FIGS. 9A and 9B illustrate one embodiment of a light-emitting device.

FIGS. 10A to 10E illustrate an example of a method for manufacturing a light-emitting device.

FIGS. 11A and 11B illustrate one embodiment of a light-emitting device.

FIGS. 12A to 12C illustrate one embodiment of a light-emitting device.

FIGS. 13A and 13B are a block diagram and a circuit diagram illustrating one embodiment of a light-emitting device.

FIGS. 14A to 14E illustrate an example of a method for manufacturing a light-emitting device.

FIGS. 15A to 15D illustrate an example of a method for manufacturing a light-emitting device.

FIGS. 16A and 16B illustrate an example of a method for manufacturing a light-emitting device.

FIGS. 17A and 17B illustrate an example of a method for manufacturing a light-emitting device.

FIGS. 18A and 18B illustrate an example of a method for manufacturing a light-emitting device.

FIGS. 19A to 19C illustrate one embodiment of a light-emitting device.

FIGS. 20A and 20B each illustrate one embodiment of a light-emitting device.

FIGS. 21A and 21B illustrate one embodiment of a light-emitting device.

FIGS. 22A and 22B illustrate structural examples of light-emitting elements.

FIGS. 23A1, 23A2, 23B1, and 23B2 illustrate one mode of a lighting device.

FIGS. 24A and 24B illustrate one embodiment of a display device.

FIGS. 25A to 25D are Cs-corrected high-resolution TEM images of a cross section of a CAAC-OS and a cross-sectional schematic view of a CAAC-OS.

FIGS. 26A to 26D are Cs-corrected high-resolution TEM images of a plane of a CAAC-OS.

FIGS. 27A to 27C show structural analysis of a CAAC-OS and a single crystal oxide semiconductor by XRD.

FIGS. 28A and 28B show electron diffraction patterns of a CAAC-OS.

FIG. 29 shows a change in crystal part of an In—Ga—Zn oxide induced by electron irradiation.

FIGS. 30A and 30B are schematic views showing deposition models of a CAAC-OS and an nc-OS.

FIGS. 31A to 31C show an InGaZnO₄ crystal and a pellet.

FIGS. 32A to 32D are schematic views illustrating a deposition model of a CAAC-OS.

### DETAILED DESCRIPTION OF THE INVENTION

Embodiments will be described in detail with reference to drawings. Note that one embodiment of the present invention is not limited to the following description, and it is easily understood by those skilled in the art that modes and details disclosed herein can be modified in various ways without departing from the spirit and the scope of the present invention. Therefore, one embodiment of the present invention is not interpreted as being limited to the description of the embodiments described below. Note that in the structures of the invention described below, the same portions or portions having similar functions are denoted by the same reference numerals in different drawings, and description of such portions is not repeated.

Note that in each drawing described in this specification, the size, the layer thickness, or the region of each component is exaggerated or omitted for clarifying the invention in some cases. Therefore, embodiments of the present invention are not limited to such a scale. Especially in a plan view (a top view) and a perspective view, some components might not be illustrated for easy understanding.

The position, size, range, and the like of each component illustrated in the drawings and the like are not accurately represented in some cases to facilitate understanding of the invention. Therefore, the disclosed invention is not necessarily limited to the position, the size, the range, or the like disclosed in the drawings and the like. For example, in the actual manufacturing process, a resist mask or the like might be unintentionally reduced in size by treatment such as etching, which is not illustrated in some cases for easy understanding.

Note that ordinal numbers such as “first” and “second” in this specification and the like are used in order to avoid confusion among components and do not denote the priority or the order such as the order of steps or the stacking order. A term without an ordinal number in this specification and the like might be provided with an ordinal number in a claim in order to avoid confusion among components.

In addition, in this specification and the like, the term such as an “electrode” or a “wiring” does not limit a function of a component. For example, an “electrode” is used as part of a “wiring” in some cases, and vice versa. Further, the term “electrode” or “wiring” can also mean a combination of a plurality of “electrodes” and “wirings” formed in an integrated manner.

Note that the term “over” or “under” in this specification and the like does not necessarily mean that a component is placed “directly on” or “directly below” and “directly in contact with” another component. For example, the expression “electrode B over insulating layer A” does not necessarily mean that the electrode B is on and in direct contact with the insulating layer A and can mean the case where another component is provided between the insulating layer A and the electrode B.

Furthermore, functions of the source and the drain might be switched depending on operation conditions, e.g., when a transistor having a different polarity is employed or a direction of current flow is changed in circuit operation. Therefore, it is difficult to define which is the source (or the drain). Thus, the terms “source” and “drain” can be switched in this specification.

Note that in this specification and the like, the expression “electrically connected” includes the case where components are connected through an “object having any electric function”. There is no particular limitation on an “object having any electric function” as long as electric signals can be transmitted and received between components that are connected through the object. Accordingly, even when the expression “to be electrically connected” is used in this specification, there is a case in which no physical connection is made and a wiring is just extended in an actual circuit.

In this specification, the term “parallel” indicates that the angle formed between two straight lines is greater than or equal to −10° and less than or equal to 10°, and accordingly also includes the case where the angle is greater than or equal to −5° and less than or equal to 5°. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°, and accordingly includes the case where the angle is greater than or equal to 85° and less than or equal to 95°. The term “substantially perpendicular” indicates that the angle formed between two straight lines is greater than or equal to 60° and less than or equal to 120°.

In this specification, trigonal and rhombohedral crystal systems are included in a hexagonal crystal system.

In this specification, in the case where an etching step is performed after a photolithography process, a resist mask formed in the photolithography process is removed after the etching step, unless otherwise specified.

### Embodiment 1

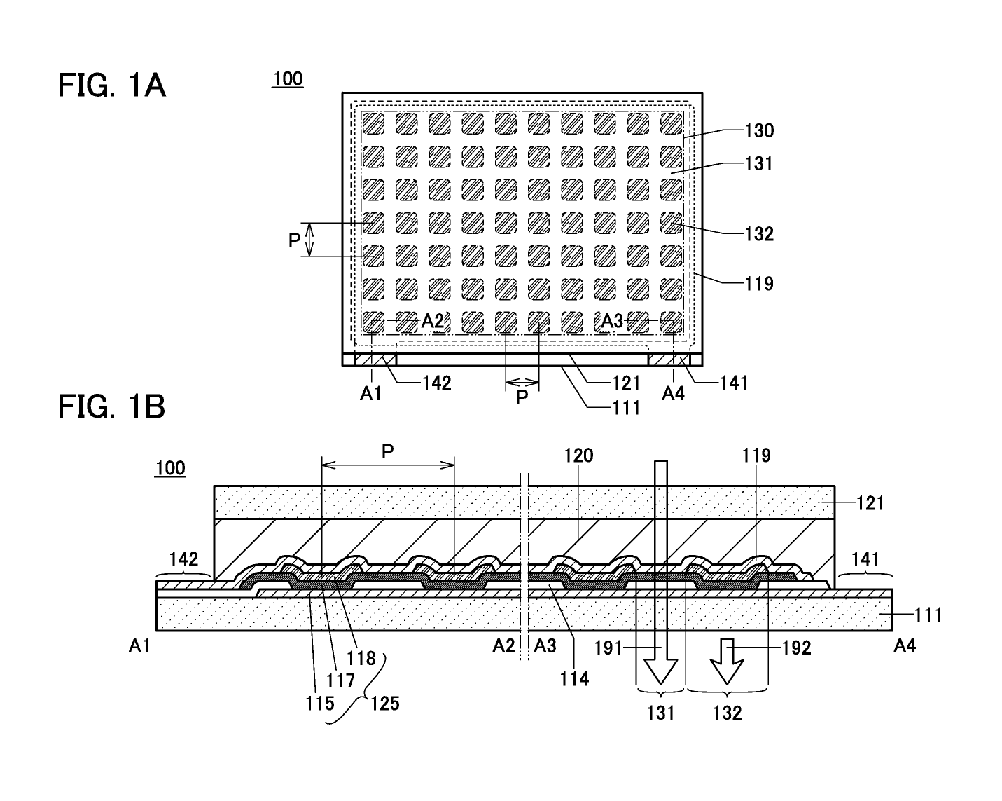

In this embodiment, a light-emitting device 100 of one embodiment of the present invention will be described with reference to FIGS. 1A and 1B, FIGS. 2A to 2F, FIGS. 3A and 3B, and FIGS. 4A and 4B. FIG. 1A is a plan view of the light-emitting device 100. In addition, FIG. 1B is a cross-sectional view of portions denoted by dashed-dotted lines A1-A2 and A3-A4 in FIG. 1A.

### <Structural Example of Light-Emitting Device>

In this embodiment, a light-emitting device having a bottom-emission structure is described as an example of the light-emitting device 100. The light-emitting device 100 includes a plurality of light-emitting portions 132 arranged in a matrix. A region in which the light-emitting portions 132 arranged in a matrix are formed is illustrated as a region 130 in FIG. 1A. In the region 130, a region in which the light-emitting portions 132 are not formed can transmit visible light. In the region 130, a region in which the light-emitting portions 132 are not formed is called a light-transmitting portion 131.

In the light-emitting device 100 described as an example in this embodiment, a substrate 111 and a substrate 121 are attached to each other with a bonding layer 120 provided therebetween. In addition, in the light-emitting device 100, an electrode 115 is formed over the substrate 111, a plurality of partitions 114 are formed over the electrode 115, an EL layer 117 is formed over the electrode 115 and the partitions 114, an electrode 118 is formed over the EL layer 117, and an electrode 119 is formed over the electrode 118.

The light-emitting portion 132 includes a light-emitting element 125. A region in which the electrode 115, the EL layer 117, and the electrode 118 overlap with one another, the electrode 115 is in contact with the EL layer 117, and the EL layer 117 is in contact with the electrode 118 functions as the light-emitting element 125.

Signals for operating the light-emitting device 100 are input to the light-emitting device 100 through a terminal 141 and a terminal 142. The terminal 141 is electrically connected to the electrode 115, and the terminal 142 is electrically connected to the electrode 119. Note that in the light-emitting device 100 described as an example in this embodiment, part of the electrode 115 functions as the terminal 141 and part of the electrode 119 functions as the terminal 142; however, another electrode functioning as the terminal 141 and another electrode functioning as the terminal 142 may be additionally provided.

Moreover, in the region 130 in which the plurality of light-emitting portions 132 arranged in a matrix are formed, a region in which the electrode 118 is not formed functions as the light-transmitting portion 131. In the light-emitting device 100, the light-transmitting portion 131 is formed to have a net-like shape.

Light 191 that is incident on the light-emitting device 100 from the substrate 121 side is transmitted to the substrate 111 side through the light-transmitting portion 131. In other words, the state of the substrate 121 side can be observed on the substrate 111 side through the light-transmitting portion 131. Since the light-emitting device 100 has a bottom-emission structure, light 192 emitted from the light-emitting element 125 is extracted to the substrate 111 side.

When the light 192 is emitted from the light-emitting portion 132, the light-emitting device 100 can function as a lighting device. Moreover, the light 192 emitted from the light-emitting portion 132 interferes with the light 191 that is incident from the substrate 121 by diffusion. By emitting the light 192 from the light-emitting portion 132, the state of the substrate 121 side can be made invisible.

The percentage (also referred to as “light transmittance”) of an area occupied by the light-transmitting portion 131 to the total area occupied by the light-transmitting portion 131 and the light-emitting portions 132 (i.e., the area of the region 130) is preferably 80% or less, further preferably 50% or less, still further preferably 20% or less. Light emission from the region 130 can be made more uniform as the light transmittance gets lower. On the other hand, when the light transmittance is high, the state of the substrate 121 side can be viewed more clearly.

In FIGS. 1A and 1B, in adjacent two light-emitting portions 132, a distance from the center of one light-emitting portion 132 to the center of the other light-emitting portion 132 is illustrated as a pitch P. When the pitch P is made small, the state of the substrate 121 side can be viewed more clearly. Moreover, when the pitch P is made small, light emission from the light-emitting portion 132 can be made more uniform. The length of the pitch P is preferably 1 cm or less, further preferably 5 mm or less, still further preferably 1 mm or less.

When the number of the light-emitting portions 132 per inch is 200 or more (200 dpi or more; about 127 μm or less on the basis of the pitch P), preferably 300 or more (300 dpi or more; about 80 μm or less on the basis of the pitch P), uniformity of light emission from the light-emitting portions 132 and visibility of the substrate 121 side can be made favorable.

Note that although the light-emitting device having a bottom-emission structure is described as an example in this embodiment, a light-emitting device having a top-emission structure or a dual-emission structure may be used.

### <Example of Manufacturing Process of Light-Emitting Device>

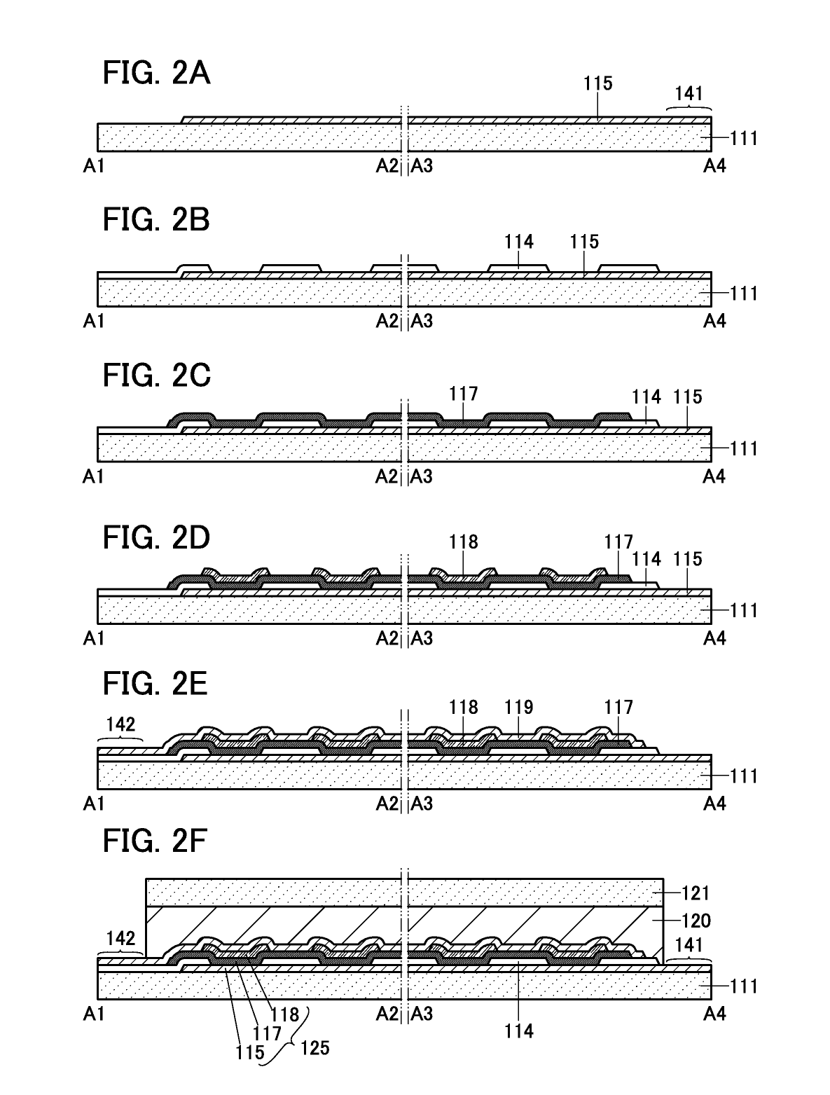

Next, an example of a manufacturing process of the light-emitting device 100 is described with reference to FIGS. 2A to 2F. FIGS. 2A to 2F are cross-sectional views of portions denoted by dashed-dotted lines A1-A2 and A3-A4 in FIG. 1A.

### [Substrate 111 and Substrate 121]

A material which has at least heat resistance high enough to withstand heat treatment to be performed later and transmits visible light can be used for the substrate 111 and the substrate 121. For example, a glass substrate or a quartz substrate can be used. With the use of an organic resin material such as plastic, the light-emitting device 100 can have flexibility. Note that a glass substrate that is thin enough to have flexibility, a quartz substrate, or the like may be used.

Examples of the organic resin material, which can be used for the substrate 111 and the substrate 121, include a polyethylene terephthalate resin, a polyethylene naphthalate resin, a polyacrylonitrile resin, a polyimide resin, a polymethylmethacrylate resin, a polycarbonate resin, a polyethersulfone resin, a polyamide resin, a cycloolefin resin, a polystyrene resin, a polyamide imide resin, and a polyvinylchloride resin.

The thermal expansion coefficients of the substrate 111 and the substrate 121 are preferably less than or equal to 30 ppm/K, further preferably less than or equal to 10 ppm/K. In addition, on surfaces of the substrate 111 and the substrate 121, a protective film having low water permeability may be formed in advance; examples of the protective film include a film containing nitrogen and silicon such as a silicon nitride film or a silicon oxynitride film and a film containing nitrogen and aluminum such as an aluminum nitride film. Note that a structure in which a fibrous body is impregnated with an organic resin (also called prepreg) may be used as the substrate 111 and the substrate 121.

With such substrates, a non-breakable display device can be provided. Alternatively, a lightweight display device can be provided. Alternatively, an easily bendable display device can be provided.

### [Formation of Electrode 115]

Next, the electrode 115 is formed over the substrate 111 (see FIG. 2A). The electrode 115 is used as an anode in the light-emitting device 100 described in this embodiment. Thus, a light-transmitting material, such as indium tin oxide, having a work function higher than that of the EL layer 117 is used for the electrode 115.

First, a conductive film used for forming the electrode 115 is provided over the substrate 111. The conductive film can be formed by a CVD method such as a plasma CVD method, an LPCVD method, a metal CVD method, or an MOCVD method, an ALD method, a sputtering method, an evaporation method, or the like. Note that a formation surface can be less damaged when the conductive film is formed by a method without plasma such as an MOCVD method.

In this embodiment, an indium tin oxide film is formed by a sputtering method as the conductive film used for forming the electrode 115.

Next, a resist mask is formed over the conductive film by a photolithography process and part of the conductive film is etched with the use of the resist mask to form the electrode 115. The resist mask can also be formed by a printing method, an ink jet method, or the like. Formation of the resist mask by an ink jet method needs no photomask; thus, manufacturing cost can be reduced.

The conductive film may be etched by a dry etching method, a wet etching method, or both a dry etching method and a wet etching method. Note that in the case where the conductive film is etched by a dry etching method, ashing treatment may be performed before the resist mask is removed, whereby the resist mask can be easily removed using a stripper.

Note that the electrode 115 may be formed by an electrolytic plating method, a printing method, an ink-jet method, or the like, instead of the above formation method.

Part of the electrode 115 is used as the terminal 141 in the light-emitting device 100 described in this embodiment.

### [Formation of Partition 114]

Next, the partitions 114 are formed over the electrode 115 (see FIG. 2B). The partitions 114 are formed using an insulating material transmitting visible light. For example, the partitions 114 can be formed using an inorganic material such as silicon oxide, silicon nitride, silicon oxynitride, silicon nitride oxide, aluminum oxide, aluminum oxynitride, or aluminum nitride oxide, or an organic resin material such as an epoxy resin, an acrylic resin, or an imide resin. In addition, the partitions 114 may have a multilayer structure in which these materials are stacked.

With the partitions 114, the light-transmitting portion 131 can be prevented from emitting light unintentionally.

The partitions 114 can be formed by a CVD method such as a plasma CVD method, an LPCVD method, a metal CVD method, or an MOCVD method, an ALD method, a sputtering method, an evaporation method, a thermal oxidation method, a coating method, a printing method, or the like.

First, an insulating film used for forming the partitions 114 is provided over the electrode 115. In this embodiment, a photosensitive imide resin deposited by a coating method is used for the insulating film. Note that when a photosensitive material is used for the partitions 114, a formation step and an etching step of a resist mask can be omitted.

The partition 114 is preferably formed so that its sidewall has a tapered shape, a stepped shape, or a tilted surface with a continuous curvature. The sidewall of the partition 114 having the above-described shape enables favorable coverage with the EL layer 117 and the electrode 118 formed later.

### [Formation of EL Layer 117]

Next, the EL layer 117 is formed over the electrode 115 and the partitions 114 (see FIG. 2C). Part of the EL layer 117 is formed in contact with part of the electrode 115. A structure of the EL layer 117 is described in Embodiment 5.

### [Formation of Electrode 118]

Next, the electrodes 118 are formed over the EL layer 117 (see FIG. 2D). The electrode 118 is used as a cathode in this embodiment, and thus is preferably formed using a material that has a low work function and can inject electrons into the EL layer 117. As well as a single-layer of a metal having a low work function, a stack in which a metal material such as aluminum (Al), titanium (Ti), tantalum (Ta), tungsten (W), molybdenum (Mo), chromium (Cr), or magnesium (Mg), a conductive oxide material such as indium tin oxide, or a semiconductor material is formed over a several-nanometer-thick buffer layer formed of an alkali metal or an alkaline earth metal having a low work function may be formed. As the buffer layer, an oxide of an alkaline earth metal, a halide, a magnesium-silver alloy, or the like can also be used.

In this embodiment, a stacked-layer structure of an aluminum film and a titanium film can be used for the electrode 118. The electrode 118 can be formed by an evaporation method using a metal mask. Moreover, in this embodiment, a several-nanometer-thick lithium fluoride film is formed between the EL layer 117 and the electrode 118 so that electrons are easily injected into the EL layer 117. The metal mask used in this embodiment is a metal plate having a plurality of openings arranged in a matrix. First, lithium fluoride, aluminum, and titanium are successively evaporated through the metal mask, whereby the lithium fluoride film and the electrodes 118 can be formed over the EL layer 117 so as to overlap with the openings of the metal mask.

### [Formation of Electrode 119]

Next, the electrode 119 is formed over the EL layer 117 and the electrode 118 (see FIG. 2E). The electrode 119 can be formed using a material and a method similar to those of the electrode 115. A plurality of electrodes 118 are electrically connected to each other through the electrode 119. Signals input from the terminal 142 are transmitted to the electrode 118 through the electrode 119.

Part of the electrode 119 is used as the terminal 142 in the light-emitting device 100 described in this embodiment.

### [Attachment of Substrate 121]

Next, the substrate 121 is formed over the substrate 111 with the bonding layer 120 provided therebetween (see FIG. 2F). A light curable adhesive, a reactive curable adhesive, a thermosetting adhesive, or an anaerobic adhesive can be used as the bonding layer 120. For example, an epoxy resin, an acrylic resin, or an imide resin can be used. The bonding layer 120 may be mixed with a drying agent (such as zeolite). Note that the bonding layer 120 and the substrate 121 are not formed over the terminal 141 and the terminal 142.

In the above-described manner, the light-emitting device 100 can be manufactured.

### <Modification Example 1 of Light-Emitting Device>

The light-emitting device 100 having a bottom-emission structure described in this embodiment can be modified into a light-emitting device 100 having a top-emission structure.

In the case where the light-emitting device 100 having a bottom-emission structure is modified into the light-emitting device 100 having a top-emission structure, the electrode 115 is formed using a material having a function of reflecting light and the electrode 118 is formed using a material having a function of transmitting light. In the light-emitting device 100 having a top-emission structure, light 192 emitted from the light-emitting element 125 is extracted to the substrate 121 side.

Note that the electrode 115 and the electrode 118 may have a stacked-layer structure of a plurality of layers without limitation to a single-layer structure. For example, in the case where the electrode 115 is used as an anode, a layer in contact with the EL layer 117 may be a light-transmitting layer, such as an indium tin oxide layer, having a work function higher than that of the EL layer 117 and a layer having high reflectance (e.g., aluminum, an alloy containing aluminum, or silver) may be provided in contact with the layer.

### <Modification Example 2 of Light-Emitting Device>

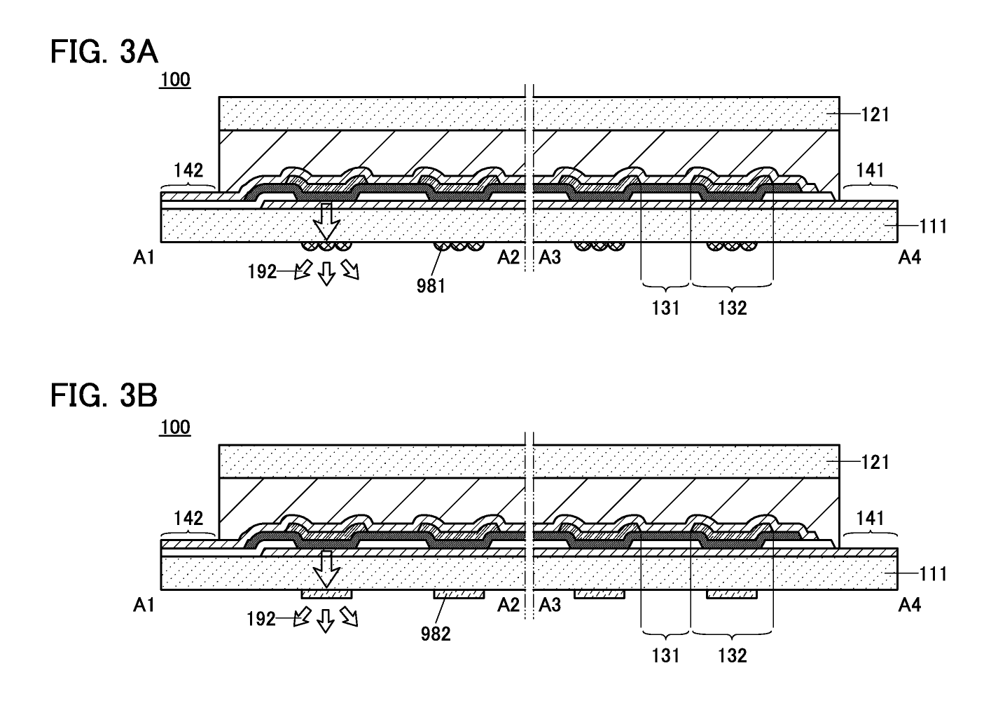

A microlens array 981 may be provided so as to overlap with the light-emitting portion 132 on the side from which the light 192 is extracted (see FIG. 3A). Alternatively, a light diffusing film 982 may be provided so as to overlap with the light-emitting portion 132 (see FIG. 3B).

The light 192 can be further diffused by being extracted through the microlens array 981 or the light diffusing film 982. Thus, light emission from the region 130 can be made more uniform.

### <Modification Example 3 of Light-Emitting Device>

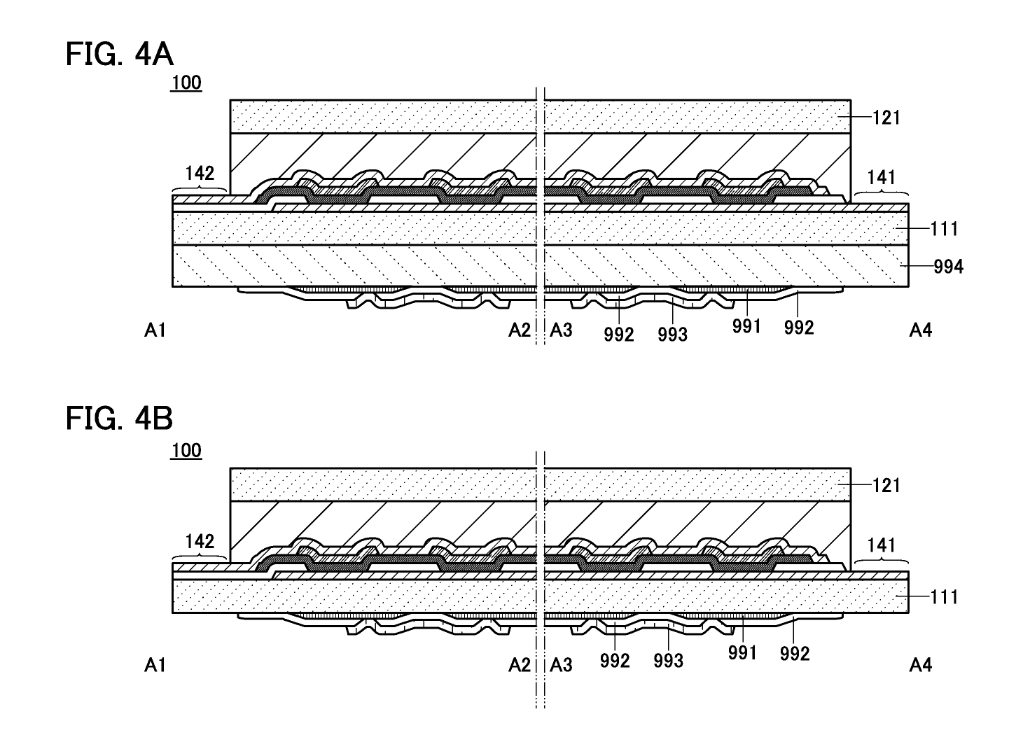

In the light-emitting device 100, a substrate provided with a touch sensor may be provided on the substrate 111 side as illustrated in FIG. 4A. The touch sensor is formed using a conductive layer 991, a conductive layer 993, and the like. In addition, an insulating layer 992 is formed between the conductive layers.

As the conductive layer 991 and/or the conductive layer 993, a transparent conductive film of indium tin oxide, indium zinc oxide, or the like is preferably used. Note that a layer containing a low-resistance material may be used for part or the whole of the conductive layer 991 and/or the conductive layer 993 in order to reduce resistance. For example, the conductive layer 991 and/or the conductive layer 993 can be formed to have a single-layer structure or a stacked-layer structure using any of metals such as aluminum, titanium, chromium, nickel, copper, yttrium, zirconium, molybdenum, silver, tantalum, and tungsten and an alloy containing any of these metals as a main component. Alternatively, a metal nanowire may be used as the conductive layer 991 and/or the conductive layer 993. Silver or the like is preferably used as a metal for the metal nanowire, in which case the resistance value can be reduced and the sensitivity of the sensor can be improved.

The insulating layer 992 is preferably formed as a single layer or a multilayer using silicon oxide, silicon nitride, silicon oxynitride, silicon nitride oxide, aluminum oxide, aluminum oxynitride, aluminum nitride oxide, or the like. The insulating layer 992 can be formed by a sputtering method, a CVD method, a thermal oxidation method, a coating method, a printing method, or the like.

Although an example in which a substrate 994 including the touch sensor is provided on the substrate 111 side is illustrated in FIG. 4A, one embodiment of the present invention is not limited thereto. The touch sensor may be provided on the substrate 121 side.

Note that the substrate 994 may have a function as an optical film. That is, the substrate 994 may have a function of a polarizing plate, a retardation plate, or the like.

Moreover, a touch sensor may be directly formed on the substrate 111 as illustrated in FIG. 4B.

This embodiment can be implemented in an appropriate combination with any of the structures described in the other embodiments.

### Embodiment 2

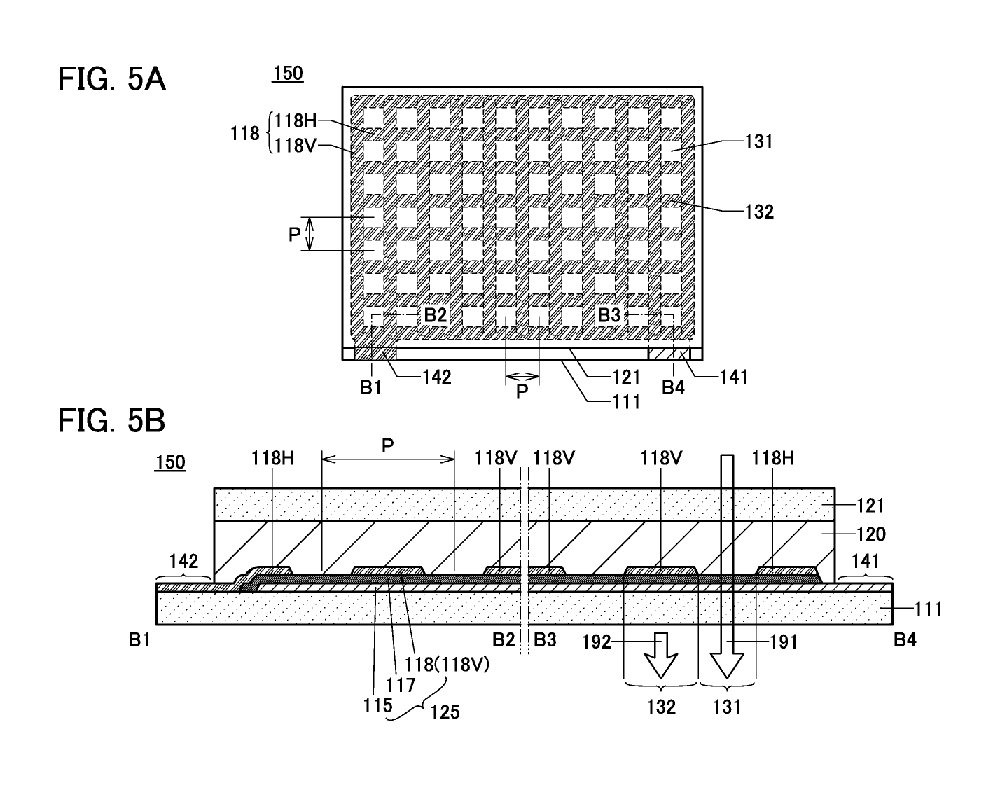

In this embodiment, a light-emitting device 150 having a structure different from the structure of the light-emitting device 100 will be described with reference to FIGS. 5A and 5B, FIGS. 6A to 6E, FIGS. 7A and 7B, and FIGS. 8A and 8B. FIG. 5A is a plan view of the light-emitting device 150. In addition, FIG. 5B is a cross-sectional view of portions denoted by dashed-dotted lines B1-B2 and B3-B4 in FIG. 5A. Note that description is made mainly on portions different from those of the light-emitting device 100 to avoid repetition of the same description.

### <Structural Example of Light-Emitting Device>

In this embodiment, a light-emitting device having a bottom-emission structure is described as an example of the light-emitting device 150. The light-emitting device 150 includes a light-emitting portion 132 which is formed to have a net-like shape and a plurality of light-transmitting portions 131 arranged in a matrix. The light-transmitting portions 131 can transmit visible light. Note that a region in which an electrode 118 is not formed functions as the light-transmitting portion 131.

In the light-emitting device 150 described as an example in this embodiment, the substrate 111 and the substrate 121 are attached to each other with the bonding layer 120 provided therebetween. In addition, in the light-emitting device 150, the electrode 115 is formed over the substrate 111, an EL layer 117 is formed over the electrode 115, and the electrode 118 is formed over the EL layer 117. The electrode 118 of the light-emitting device 150 includes an electrode 118H which is extended in a horizontal direction and an electrode 118V which is extended in a vertical direction. In the case where an electrode is simply described as the electrode 118 in this embodiment, it refers either the electrode 118H or the electrode 118V or both the electrode 118H and the electrode 118V.

Note that in the light-emitting device 150 described as an example in this embodiment, part of the electrode 115 functions as the terminal 141 and part of the electrode 118 functions as the terminal 142; however, another electrode functioning as the terminal 141 and another electrode functioning as the terminal 142 may be additionally provided.

In a manner similar to that of the light-emitting device 100 described as an example in Embodiment 1, light 191 that is incident on the light-emitting device 150 from the substrate 121 side is transmitted to the substrate 111 side through the light-transmitting portions 131. In other words, the state of the substrate 121 side can be observed on the substrate 111 side through the light-transmitting portions 131. Since the light-emitting device 150 has a bottom-emission structure, light 192 emitted from the light-emitting element 125 is extracted to the substrate 111 side. Furthermore, in the light-emitting device 150, light is emitted from the light-emitting portion 132 in a net-like manner; therefore, the region 130 has high uniformity of light intensity distribution. Thus, according to the light-emitting device 150 of one embodiment of the present invention, a lighting device having a favorably uniform planar light source can be achieved.

In a manner similar to that of the light-emitting device 100 described as an example in Embodiment 1, the percentage (also referred to as “light transmittance”) of an area occupied by the light-transmitting portions 131 to the total area occupied by the light-transmitting portions 131 and the light-emitting portion 132 is preferably 80% or less, further preferably 50% or less, still further preferably 20% or less. Light emission from the region 130 can be made more uniform as the light transmittance gets lower. On the other hand, when the light transmittance is high, the state of the substrate 121 side can be viewed more clearly.

In FIGS. 5A and 5B, in adjacent two light-transmitting portions 131, a distance from the center of one light-transmitting portion 131 to the center of the other light-transmitting portion 131 is illustrated as a pitch P. When the pitch P is made small, the state of the substrate 121 side can be viewed more clearly. Moreover, when the pitch P is made small, light emission from the light-emitting portion 132 can be made more uniform. The length of the pitch P is preferably 1 cm or less, further preferably 5 mm or less, still further preferably 1 mm or less.

When the number of the light-transmitting portions 131 per inch is 200 or more (200 dpi or more; about 127 μm or less on the basis of the pitch P), preferably 300 or more (300 dpi or more; about 80 μm or less on the basis of the pitch P), uniformity of light emission from the light-emitting portion 132 and visibility of the substrate 121 side can be made favorable.

Alternatively, a microlens array, a light diffusing film, or the like may be provided so as to overlap with the light-emitting portion 132.

Note that although the light-emitting device having a bottom-emission structure is described as an example in this embodiment, a light-emitting device having a top-emission structure or a dual-emission structure may be used.

### <Example of Manufacturing Process of Light-Emitting Device>

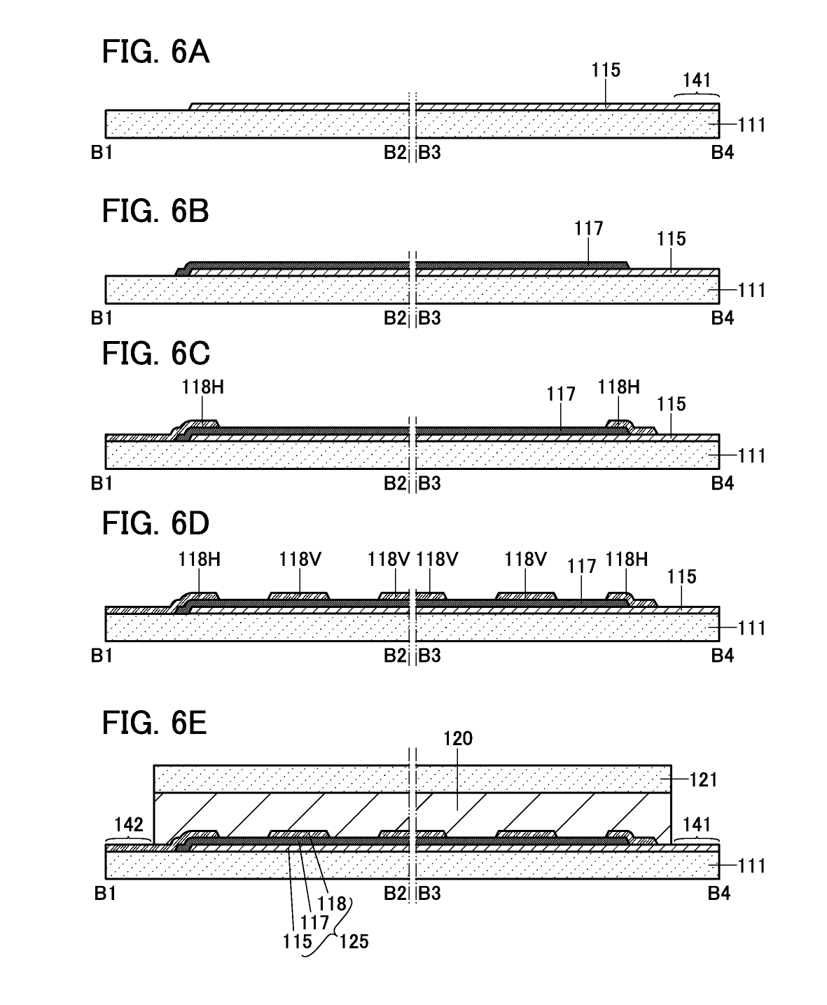

Next, an example of a manufacturing process of the light-emitting device 150 is described with reference to FIGS. 6A to 6E. FIGS. 6A to 6E are cross-sectional views of portions denoted by dashed-dotted lines B1-B2 and B3-B4 in FIG. 5A.

### [Substrate 111 and Substrate 121]

A material similar to that in Embodiment 1 can be used for the substrate 111 and the substrate 121.

### [Formation of Electrode 115]

Next, the electrode 115 is formed over the substrate 111 (see FIG. 6A). The electrode 115 can be formed using a material and a method similar to those in Embodiment 1.

[Formation of EL layer 117]

Next, the EL layer 117 is formed over the electrode 115 (see FIG. 6B). A structure of the EL layer 117 is described in Embodiment 5.

### [Formation of Electrode 118]

Next, the electrodes 118 are formed over the EL layer 117. The electrodes 118 can be formed using a material and a method similar to those in Embodiment 1. First, lithium fluoride and aluminum are evaporated through a metal mask having a plurality of openings extended in a horizontal direction to form the electrodes 118H (see FIG. 6C). Subsequently, lithium fluoride and aluminum are evaporated through a metal mask having a plurality of openings extended in a vertical direction to form the electrodes 118V (see FIG. 6D). Thus, the electrode 118H and the electrode 118V are electrically connected to each other.

Alternatively, after the electrodes 118H are formed, the same metal mask is used to rotate the substrate 111 90° in a horizontal direction so that the electrodes 118V can be formed.

### [Attachment of Substrate 121]

Next, the substrate 121 is formed over the substrate 111 with the bonding layer 120 provided therebetween in a manner similar to that of Embodiment 1 (see FIG. 6E).

In the above-described manner, the light-emitting device 150 can be manufactured.

### <Modification Example 1 of Light-Emitting Device>

The light-emitting device 150 having a bottom-emission structure described in this embodiment can be modified into a light-emitting device 150 having a top-emission structure.

In the case where the light-emitting device 150 having a bottom-emission structure is modified into the light-emitting device 150 having a top-emission structure, the electrode 115 is formed using a material having a function of reflecting light and the electrode 118 is formed using a material having a function of transmitting light. In the light-emitting device 150 having a top-emission structure, the light 192 emitted from the light-emitting element 125 is extracted to the substrate 121 side.

Note that the electrode 115 and the electrode 118 may have a stacked-layer structure of a plurality of layers without limitation to a single-layer structure. For example, in the case where the electrode 115 is used as an anode, a layer in contact with the EL layer 117 may be a light-transmitting layer, such as an indium tin oxide layer, having a work function higher than that of the EL layer 117 and a layer having high reflectance (e.g., aluminum, an alloy containing aluminum, or silver) may be provided in contact with the layer.

### <Modification Example 2 of Light-Emitting Device>

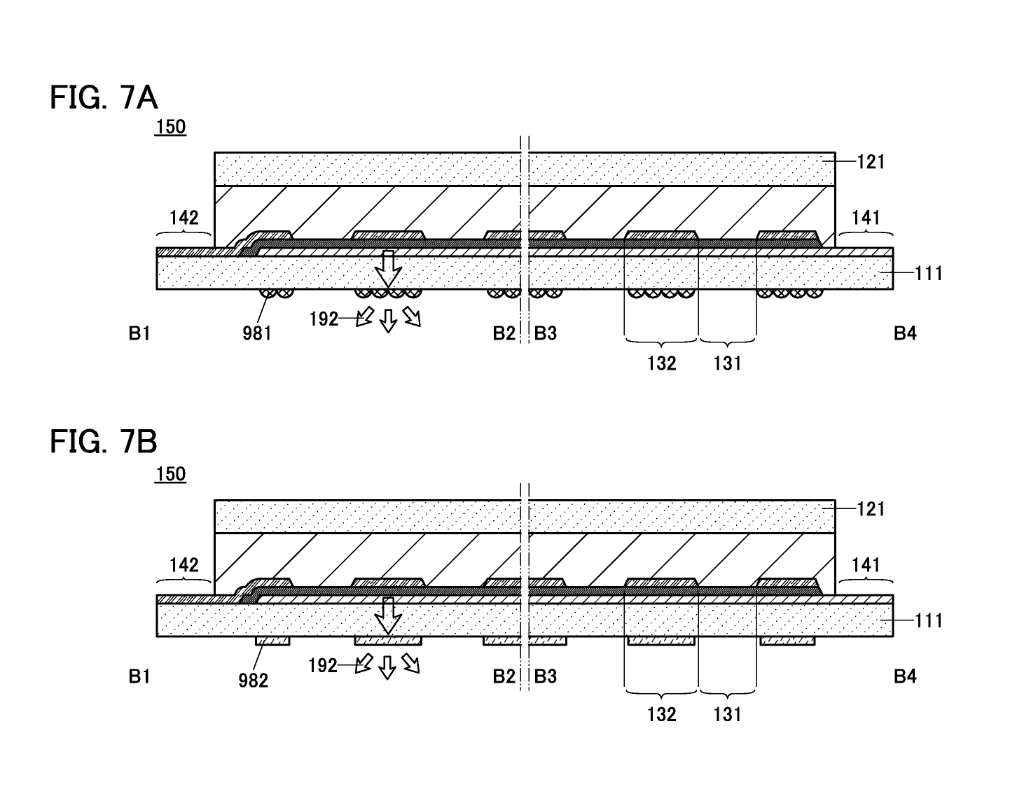

The microlens array 981 may be provided so as to overlap with the light-emitting portion 132 on the side from which the light 192 is extracted (see FIG. 7A). Alternatively, the light diffusing film 982 may be provided so as to overlap with the light-emitting portion 132 (see FIG. 7B).

The light 192 can be further diffused by being extracted through the microlens array 981 or the light diffusing film 982. Thus, light emission from the region 130 can be made more uniform.

### <Modification Example 3 of Light-Emitting Device>

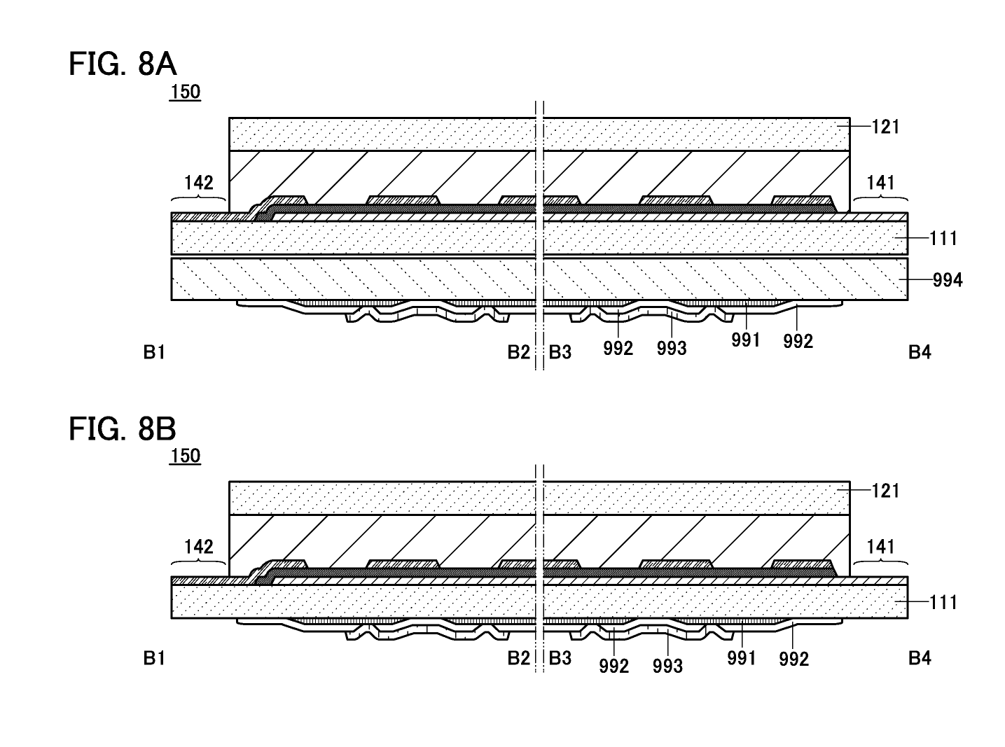

In the light-emitting device 150, a substrate provided with a touch sensor may be provided on the substrate 111 side as illustrated in FIG. 8A. The touch sensor is formed using the conductive layer 991, the conductive layer 993, and the like. In addition, the insulating layer 992 is formed between the conductive layers.

As the conductive layer 991 and/or the conductive layer 993, a transparent conductive film of indium tin oxide, indium zinc oxide, or the like is preferably used. Note that a layer containing a low-resistance material may be used for part or the whole of the conductive layer 991 and/or the conductive layer 993 in order to reduce resistance. For example, the conductive layer 991 and/or the conductive layer 993 can be formed to have a single-layer structure or a stacked-layer structure using any of metals such as aluminum, titanium, chromium, nickel, copper, yttrium, zirconium, molybdenum, silver, tantalum, and tungsten and an alloy containing any of these metals as a main component. Alternatively, a metal nanowire may be used as the conductive layer 991 and/or the conductive layer 993. Silver or the like is preferably used as a metal for the metal nanowire, in which case the resistance value can be reduced and the sensitivity of the sensor can be improved.

The insulating layer 992 is preferably formed as a single layer or a multilayer using silicon oxide, silicon nitride, silicon oxynitride, silicon nitride oxide, aluminum oxide, aluminum oxynitride, aluminum nitride oxide, or the like. The insulating layer 992 can be formed by a sputtering method, a CVD method, a thermal oxidation method, a coating method, a printing method, or the like.

Although an example in which the touch sensor is provided on the substrate 111 side is illustrated in FIG. 8A, one embodiment of the present invention is not limited thereto. The touch sensor may be provided on the substrate 121 side.

Note that the substrate 994 may have a function as an optical film. That is, the substrate 994 may have a function of a polarizing plate, a retardation plate, or the like.

Moreover, a touch sensor may be directly formed on the substrate 111 as illustrated in FIG. 8B.

This embodiment can be implemented in an appropriate combination with any of the structures described in the other embodiments.

### Embodiment 3

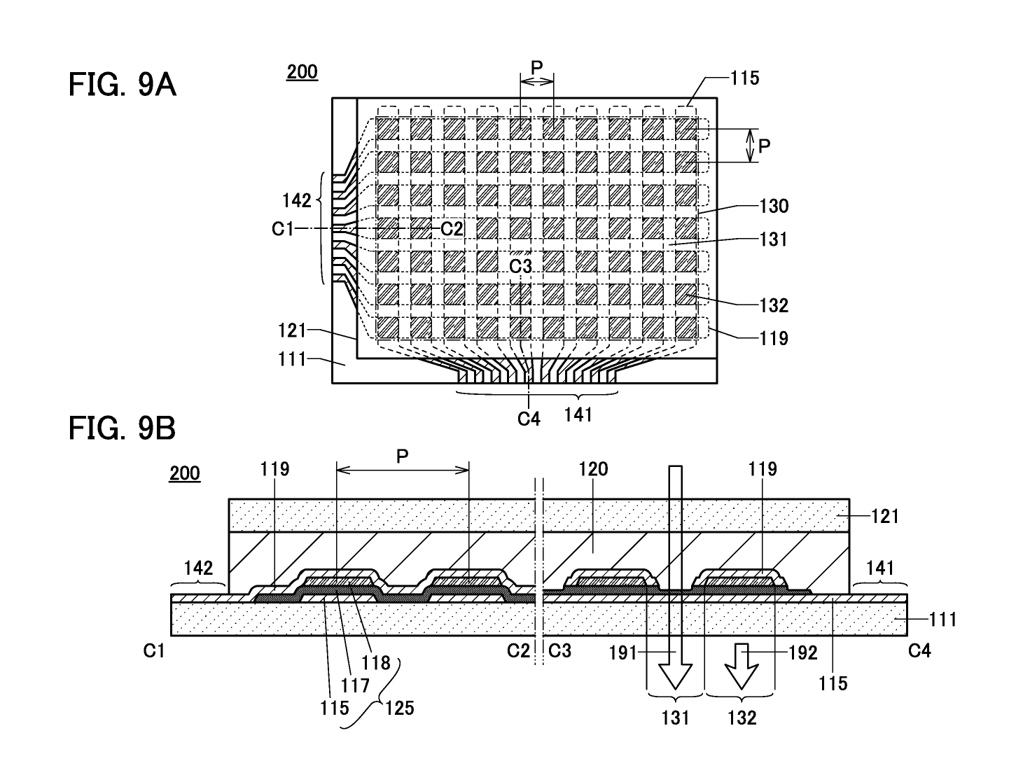

In this embodiment, a light-emitting device 200 having a structure different from the structures of the light-emitting device 100 and the light-emitting device 150 will be described with reference to FIGS. 9A and 9B, FIGS. 10A to 10E, and FIGS. 11A and 11B. FIG. 9A is a plan view of the light-emitting device 200. In addition, FIG. 9B is a cross-sectional view of portions denoted by dashed-dotted lines C1-C2 and C3-C4 in FIG. 9A. Note that description is made mainly on portions different from those of the light-emitting device 100 and the light-emitting device 150 to avoid repetition of the same description.

### <Structural Example of Light-Emitting Device>

In this embodiment, a light-emitting device having a bottom-emission structure is described as an example of the light-emitting device 200. The light-emitting device 200 includes the plurality of light-emitting portions 132 arranged in a matrix. A region in which the light-emitting portions 132 arranged in a matrix are formed is illustrated as a region 130 in FIG. 9A. In the region 130, a region in which the light-emitting portions 132 are not formed can transmit visible light. In the region 130, a region in which the light-emitting portions 132 are not formed is called a light-transmitting portion 131.

In the light-emitting device 200 described as an example in this embodiment, the substrate 111 and the substrate 121 are attached to each other with the bonding layer 120 provided therebetween. In addition, in the light-emitting device 200, a plurality of stripe-shaped electrodes 115 are formed over the substrate 111, an EL layer 117 is formed over the electrode 115, a plurality of electrodes 118 are formed over the EL layer 117, and a plurality of stripe-shaped electrodes 119 are formed over the electrodes 118. In FIG. 9A, the electrodes 115 extend in vertical directions and the electrodes 119 extend in horizontal directions. The extending directions of the electrode 115 and the electrode 119 intersect with each other.

A region in which the electrode 115 and the electrode 119 overlap with each other functions as the light-emitting portion 132. Furthermore, the electrode 118 is formed in a region in which the electrode 115 and the electrode 119 overlap with each other. The light-emitting portion 132 includes the light-emitting element 125. A region in which the electrode 115, the EL layer 117, and the electrode 118 overlap with one another functions as the light-emitting element 125.

Signals for operating the light-emitting device 200 are input to the light-emitting device 200 through the terminal 141 and the terminal 142. The terminal 141 is electrically connected to the electrode 115, and the terminal 142 is electrically connected to the electrode 119. The light-emitting device 200 includes the plurality of electrodes 115 to which different signals or the same signals can be supplied through the terminal 141. The light-emitting device 200 includes the plurality of electrodes 119 to which different signals or the same signals can be supplied through the terminal 142. Note that in the light-emitting device 200 described as an example in this embodiment, part of the electrode 115 functions as the terminal 141 and part of the electrode 119 functions as the terminal 142; however, another electrode functioning as the terminal 141 and another electrode functioning as the terminal 142 may be additionally provided.

Moreover, in the region 130 in which the plurality of light-emitting portions 132 arranged in a matrix are formed, a region in which the electrode 118 is not formed functions as the light-transmitting portion 131. In the light-emitting device 200, the light-transmitting portion 131 is formed to have a net-like shape.

Light 191 that is incident on the light-emitting device 200 from the substrate 121 side is transmitted to the substrate 111 side through the light-transmitting portion 131. In other words, the state of the substrate 121 side can be observed on the substrate 111 side through the light-transmitting portion 131. Since the light-emitting device 200 has a bottom-emission structure, light 192 emitted from the light-emitting element 125 is extracted to the substrate 111 side.

Signals are supplied by selecting, as appropriate, the plurality of electrodes 115 and the plurality of electrodes 119, whereby light at given luminance can be emitted from a given light-emitting element 125 that exists at an intersection of the electrode 115 and the electrode 119. When light at given luminance is emitted or not emitted from the plurality of light-emitting elements 125, characters or images can be displayed on the region 130. Thus, the light-emitting device 200 described in this embodiment can function not only as a lighting device but also as a display device.

The percentage (also referred to as “light transmittance”) of an area occupied by the light-transmitting portion 131 to the total area occupied by the light-transmitting portion 131 and the light-emitting portions 132 (the area of the region 130) is preferably 80% or less, further preferably 50% or less, still further preferably 20% or less. Light emission from the region 130 can be made more uniform as the light transmittance gets lower; accordingly, an image having a high display quality can be displayed. On the other hand, when the light transmittance is high, the state of the substrate 121 side can be viewed more clearly.

In FIGS. 9A and 9B, in adjacent two light-emitting portions 132, a distance from the center of one light-emitting portion 132 to the center of the other light-emitting portion 132 is illustrated as a pitch P. When the pitch P is made small, the state of the substrate 121 side can be viewed more clearly. Moreover, when the pitch P is made small, light emission from the light-emitting portion 132 can be made more uniform. The length of the pitch P is preferably 1 cm or less, further preferably 5 mm or less, still further preferably 1 mm or less.

When the number of the light-emitting portions 132 per inch is 200 or more (200 dpi or more; about 127 μm or less on the basis of the pitch P), preferably 300 or more (300 dpi or more; about 80 μm or less on the basis of the pitch P), uniformity of light emission from the light-emitting portions 132 and visibility of the substrate 121 side can be made favorable. Moreover, an image having a high display quality can be displayed.

Alternatively, a microlens array, a light diffusing film, or the like may be provided so as to overlap with the light-emitting portion 132.

Note that although the light-emitting device having a bottom-emission structure is described as an example in this embodiment, a light-emitting device having a top-emission structure or a dual-emission structure may be used.

### <Example of Manufacturing Process of Light-emitting Device>

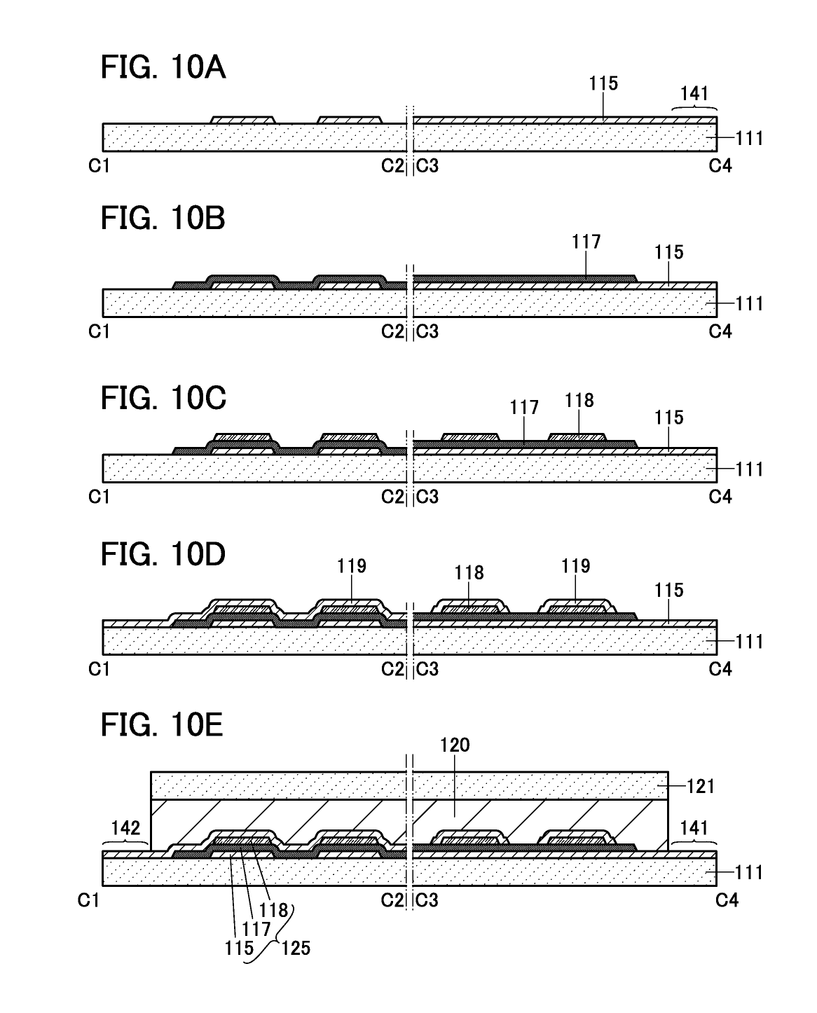

Next, an example of a manufacturing process of the light-emitting device 200 is described with reference to FIGS. 10A to 10E. FIGS. 10A to 10E are cross-sectional views of portions denoted by dashed-dotted lines C1-C2 and C3-C4 in FIG. 9A.

### [Substrate 111 and Substrate 121]

A material similar to that in Embodiment 1 can be used for the substrate 111 and the substrate 121.

### [Formation of Electrode 115]

Next, the electrode 115 is formed over the substrate 111 (see FIG. 10A). The electrode 115 can be formed using a material and a method similar to those in Embodiment 1.

### [Formation of EL Layer 117]

Next, the EL layer 117 is formed over the electrode 115 (see FIG. 10B). A structure of the EL layer 117 is described in Embodiment 5.

### [Formation of Electrode 118]

Next, the electrode 118 is formed over the EL layer 117 (see FIG. 10C). The electrode 118 can be formed using a material and a method similar to those in Embodiment 1.

### [Formation of Electrode 119]

Next, the electrode 119 is formed over the EL layer 117 and the electrode 118 (see FIG. 10D). The electrode 119 can be formed using a material and a method similar to those of the electrode 115. A plurality of electrodes 118 overlapping with the electrodes 119 are electrically connected to each other. Note that when the electrode 119 is formed, part of the EL layer 117 might be removed.

In this embodiment, an example in which part of the electrode 119 functions as the terminal 142 is shown. Signals input from the terminal 142 are transmitted to the electrode 118 through the electrode 119.

### [Attachment of Substrate 121]

Next, the substrate 121 is formed over the substrate 111 with the bonding layer 120 provided therebetween in a manner similar to that of Embodiment 1 (see FIG. 10E).

In the above-described manner, the light-emitting device 200 can be manufactured.

### <Modification Example 1 of Light-Emitting Device>

The light-emitting device 200 having a bottom-emission structure described in this embodiment can be modified into a light-emitting device 200 having a top-emission structure.

In the case where the light-emitting device 200 having a bottom-emission structure is modified into the light-emitting device 200 having a top-emission structure, the electrode 115 is formed using a material having a function of reflecting light and the electrode 118 is formed using a material having a function of transmitting light. In the light-emitting device 200 having a top-emission structure, the light 192 emitted from the light-emitting element 125 is extracted to the substrate 121 side.

Note that the electrode 115 and the electrode 118 may have a stacked-layer structure of a plurality of layers without limitation to a single-layer structure. For example, in the case where the electrode 115 is used as an anode, a layer in contact with the EL layer 117 may be a light-transmitting layer, such as an indium tin oxide layer, having a work function higher than that of the EL layer 117 and a layer having high reflectance (e.g., aluminum, an alloy containing aluminum, or silver) may be provided in contact with the layer.

### <Modification Example 2 of Light-Emitting Device>

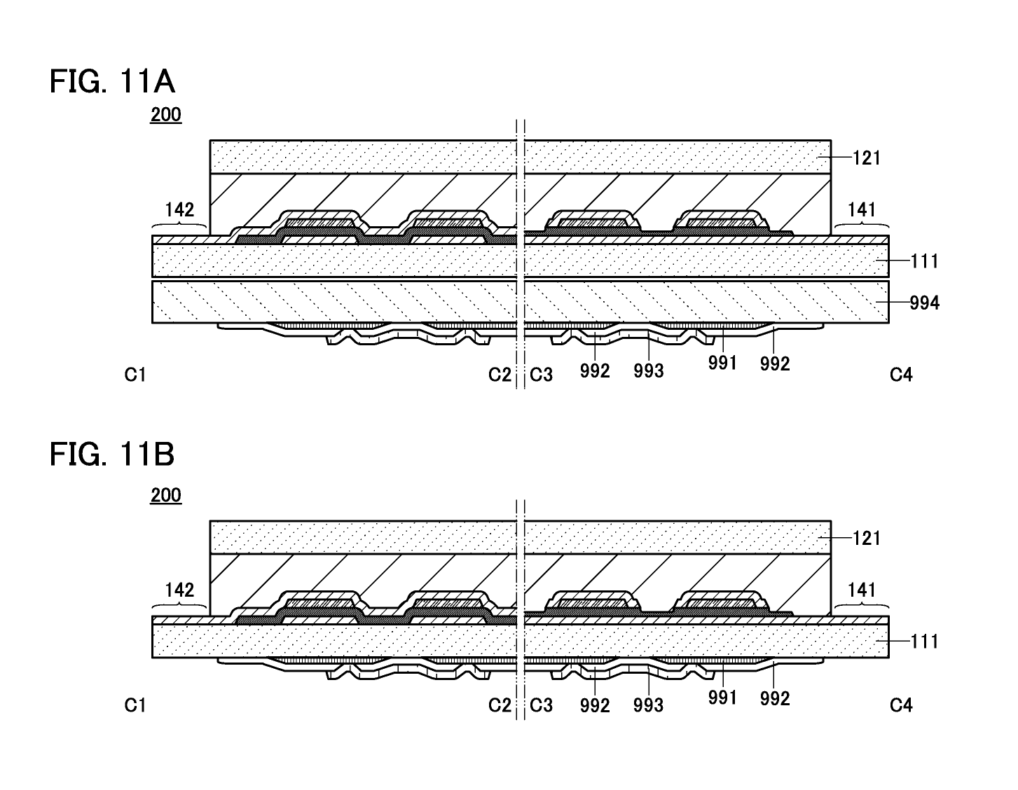

In the light-emitting device 200, a substrate provided with a touch sensor may be provided on the substrate 111 side as illustrated in FIG. 11A. The touch sensor is formed using the conductive layer 991, the conductive layer 993, and the like. In addition, the insulating layer 992 is formed between the conductive layers.

As the conductive layer 991 and/or the conductive layer 993, a transparent conductive film of indium tin oxide, indium zinc oxide, or the like is preferably used. Note that a layer containing a low-resistance material may be used for part or the whole of the conductive layer 991 and/or the conductive layer 993 in order to reduce resistance. For example, the conductive layer 991 and/or the conductive layer 993 can be formed as a single layer or a stack using any of metals such as aluminum, titanium, chromium, nickel, copper, yttrium, zirconium, molybdenum, silver, tantalum, and tungsten and an alloy containing any of these metals as a main component. Alternatively, a metal nanowire may be used as the conductive layer 991 and/or the conductive layer 993. Silver or the like is preferably used as a metal for the metal nanowire, in which case the resistance value can be reduced and the sensitivity of the sensor can be improved.

The insulating layer 992 is preferably formed as a single layer or a multilayer using silicon oxide, silicon nitride, silicon oxynitride, silicon nitride oxide, aluminum oxide, aluminum oxynitride, aluminum nitride oxide, or the like. The insulating layer 992 can be formed by a sputtering method, a CVD method, a thermal oxidation method, a coating method, a printing method, or the like.

Although an example in which the touch sensor is provided on the substrate 111 side is illustrated in FIG. 11A, one embodiment of the present invention is not limited thereto. The touch sensor may be provided on the substrate 121 side.

Note that the substrate 994 may have a function as an optical film. That is, the substrate 994 may have a function of a polarizing plate, a retardation plate, or the like.

Moreover, a touch sensor may be directly formed on the substrate 111 as illustrated in FIG. 11B.

This embodiment can be implemented in an appropriate combination with any of the structures described in the other embodiments.

### Embodiment 4

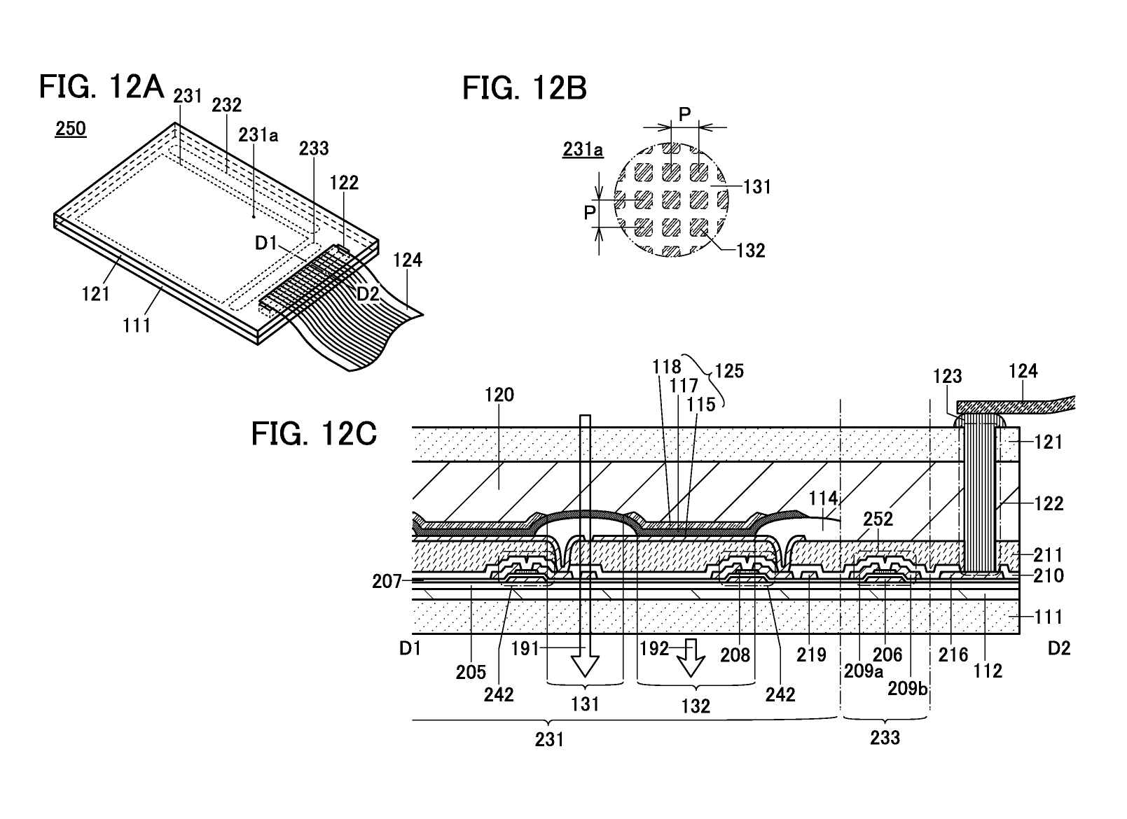

In this embodiment, a light-emitting device 250 having a structure different from the structures of the light-emitting device 100, the light-emitting device 150, and the light-emitting device 200 will be described with reference to FIGS. 12A to 12C, FIGS. 13A and 13B, FIGS. 14A to 14E, FIGS. 15A to 15D, FIGS. 16A and 16B, FIGS. 17A and 17B, FIGS. 18A and 18B, FIGS. 19A to 19C, FIGS. 20A and 20B, and FIGS. 21A and 21B. FIG. 12A is a perspective view of the light-emitting device 250. The light-emitting device 250 described in this embodiment includes a display region 231, a driver circuit 232, and a driver circuit 233. FIG. 12B is an enlarged view of part of the display region 231 which is illustrated as a portion 231a in FIG. 12A. In addition, FIG. 12C is a cross-sectional view of a portion denoted by a dashed-dotted line D1-D2 in FIG. 12A. Note that description is made mainly on portions different from those of the light-emitting device 100, the light-emitting device 150, and the light-emitting device 200 to avoid repetition of the same description.

### <Structural Example of Light-Emitting Device>

In this embodiment, a light-emitting device having a bottom-emission structure is described as an example of the light-emitting device 250. The light-emitting device 250 includes a plurality of light-emitting portions 132 arranged in a matrix. The plurality of light-emitting portions 132 are arranged in a matrix in the display region 231. The light-emitting portions 132 each include the light-emitting element 125 including the electrode 115, the EL layer 117, and the electrode 118. A transistor 242 for controlling the amount of light emitted from the light-emitting element 125 is connected to each of the light-emitting elements 125. In the display region 231, a region in which the light-emitting portions 132 are not formed includes a region which transmits visible light. In the display region 231, a region which transmits visible light is called a light-transmitting portion 131. The light-emitting device 250 described as an example in this embodiment functions as an active-matrix display device.

The light-emitting device 250 also includes a terminal electrode 216. An external electrode 124 and the terminal electrode 216 are electrically connected to each other through an anisotropic conductive connection layer 123. In addition, the terminal electrode 216 is electrically connected to the driver circuit 232 and the driver circuit 233.

The driver circuit 232 and the driver circuit 233 each include a plurality of transistors 252. The driver circuit 232 and the driver circuit 233 each have a function of determining which of the light-emitting elements 125 in the display region 231 is supplied with a signal from the external electrode 124.

The transistor 242 and the transistor 252 each include a gate electrode 206, a gate insulating layer 207, a semiconductor layer 208, a source electrode 209a, and a drain electrode 209b. A wiring 219 is formed in the same layer as the source electrode 209a and the drain electrode 209b. In addition, an insulating layer 210 is formed over the transistor 242 and the transistor 252, and an insulating layer 211 is formed over the insulating layer 210. The electrode 115 is formed over the insulating layer 211. The electrode 115 is electrically connected to the drain electrode 209b through an opening formed in the insulating layer 210 and the insulating layer 211. The partition 114 is formed over the electrode 115, and the EL layer 117 and the electrode 118 are formed over the electrode 115 and the partition 114.

In the light-emitting device 250, the substrate 111 and the substrate 121 are attached to each other with the bonding layer 120 provided therebetween.

An insulating layer 205 is formed over the substrate 111 with a bonding layer 112 provided therebetween. The insulating layer 205 is preferably formed as a single layer or a multilayer using silicon oxide, silicon nitride, silicon oxynitride, silicon nitride oxide, aluminum oxide, aluminum oxynitride, aluminum nitride oxide, or the like. The insulating layer 205 can be formed by a sputtering method, a CVD method, a thermal oxidation method, a coating method, a printing method, or the like.

Note that the insulating layer 205 functions as a base layer and can prevent or reduce diffusion of moisture and impurity elements from the substrate 111, the bonding layer 112, or the like to the transistor or the light-emitting element.

In the light-emitting device 250 described as an example in this embodiment, when light at given luminance is emitted or not emitted from the plurality of light-emitting elements 125, characters or images can be displayed on the display region 231. Thus, the light-emitting device 250 described in this embodiment can function not only as a lighting device but also as a display device. Furthermore, the amount of light emission from each light-emitting element 125 in the light-emitting device 250 described as an example in this embodiment can be controlled more precisely than that in the light-emitting device 200 described as an example in the above embodiment.

According to one embodiment of the present invention, a display device having a high display quality can be achieved. In addition, according to one embodiment of the present invention, a display device having low power consumption can be achieved.

The percentage (also referred to as “light transmittance”) of an area occupied by the light-transmitting portion 131 to an area occupied by the display region 231 is preferably 80% or less, further preferably 50% or less, still further preferably 20% or less. Light emission from the display region 231 can be made more uniform as the light transmittance gets lower; accordingly, an image having a high display quality can be displayed. On the other hand, when the light transmittance is high, the state of the substrate 121 side can be viewed more clearly.

In FIG. 12B, in adjacent two light-emitting portions 132, a distance from the center of one light-emitting portion 132 to the center of the other light-emitting portion 132 is illustrated as a pitch P. When the pitch P is made small, the state of the substrate 121 side can be viewed more clearly. Moreover, when the pitch P is made small, light emission from the light-emitting portion 132 can be made more uniform. The length of the pitch P is preferably 1 cm or less, further preferably 5 mm or less, still further preferably 1 mm or less.

When the number of the light-emitting portions 132 per inch is 200 or more (200 dpi or more; about 127 μm or less on the basis of the pitch P), preferably 300 or more (300 dpi or more; about 80 μm or less on the basis of the pitch P), uniformity of light emission from the light-emitting portions 132 and visibility of the substrate 121 side can be made favorable. Moreover, an image having a high display quality can be displayed.

Alternatively, a microlens array, a light diffusing film, or the like may be provided so as to overlap with the light-emitting portion 132.

Note that although the light-emitting device having a bottom-emission structure is described as an example in this embodiment, a light-emitting device having a top-emission structure or a dual-emission structure may be used.

### <Example of Pixel Circuit Configuration>

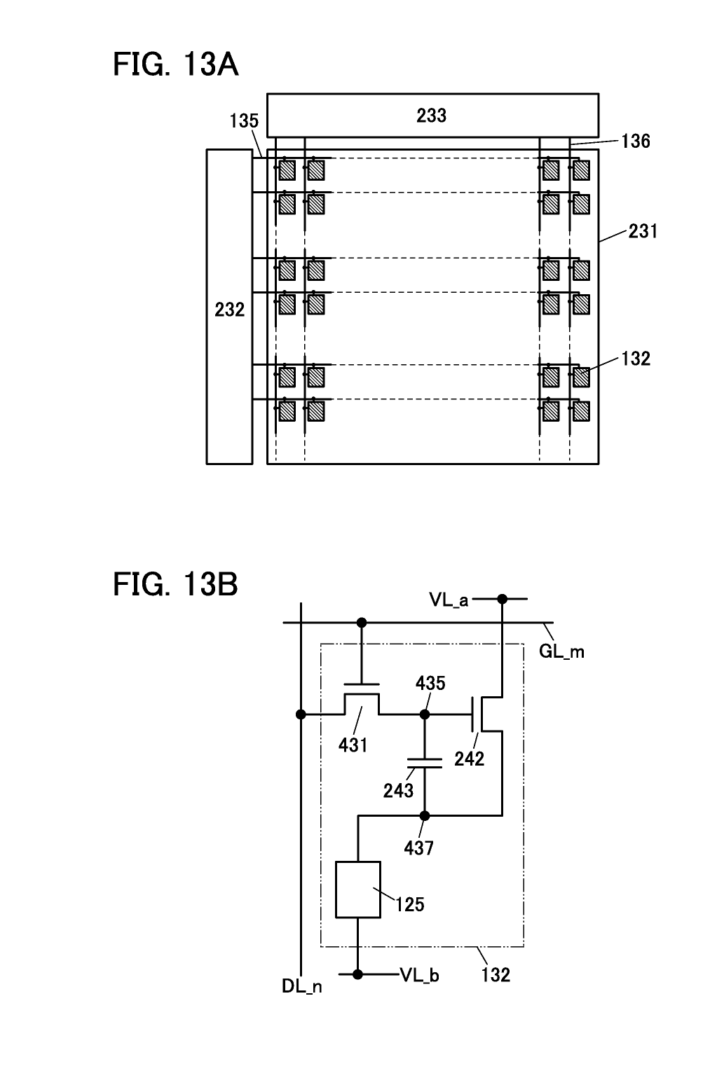

Next, a specific structural example of the light-emitting device 250 is described with reference to FIGS. 13A and 13B. FIG. 13A is a block diagram illustrating the configuration of the light-emitting device 250. The light-emitting device 250 includes the display region 231, the driver circuit 232, and the driver circuit 233. The driver circuit 232 functions as a scan line driver circuit, for example, and the driver circuit 233 functions as a signal line driver circuit, for example.

The light-emitting device 250 includes m scan lines 135 which are arranged parallel or substantially parallel to each other and whose potentials are controlled by the driver circuit 232, and n signal lines 136 which are arranged parallel or substantially parallel to each other and whose potentials are controlled by the driver circuit 233. The display region 231 includes a plurality of light-emitting portions 132 arranged in a matrix. The driver circuit 232 and the driver circuit 233 are collectively referred to as a driver circuit portion in some cases.

Each of the scan lines 135 is electrically connected to the n light-emitting portions 132 in the corresponding row among the light-emitting portions 132 arranged in m rows and n columns in the display region 231. Each of the signal lines 136 is electrically connected to the m light-emitting portions 132 in the corresponding column among the light-emitting portions 132 arranged in m rows and n columns. Note that m and n are each an integer of 1 or more.

### [Example of Pixel Circuit for Light-Emitting Display Device]

FIG. 13B illustrates a circuit configuration that can be used for the light-emitting portions 132 in the display device illustrated in FIG. 13A. The light-emitting portion 132 illustrated in FIG. 13B includes a transistor 431, a capacitor 243, the transistor 242, and the light-emitting element 125.

One of a source electrode and a drain electrode of the transistor 431 is electrically connected to a wiring to which a data signal is supplied (hereinafter referred to as a signal line DL_n). A gate electrode of the transistor 431 is electrically connected to a wiring to which a gate signal is supplied (hereinafter referred to as a scan line GL_m).

The transistor 431 has a function of controlling whether to write a data signal to a node 435 by being turned on or off.

One of a pair of electrodes of the capacitor 243 is electrically connected to the node 435, and the other is electrically connected to the node 437. The other of the source electrode and the drain electrode of the transistor 431 is electrically connected to the node 435.

The capacitor 243 functions as a storage capacitor for storing data written to the node 435.

One of a source electrode and a drain electrode of the transistor 242 is electrically connected to a potential supply line VL_a, and the other is electrically connected to the node 437. Furthermore, a gate electrode of the transistor 242 is electrically connected to the node 435.

One of an anode and a cathode of the light-emitting element 125 is electrically connected to a potential supply line VL_b, and the other is electrically connected to the node 437.

As the light-emitting element 125, an organic electroluminescent element (also referred to as an organic EL element) can be used, for example. Note that the light-emitting element 125 is not limited to organic EL elements; an inorganic EL element including an inorganic material can be used.

A high power supply potential VDD is supplied to one of the potential supply line VL_a and the potential supply line VL_b, and a low power supply potential VSS is supplied to the other.

In the display device including the light-emitting portion 132 in FIG. 13B, the light-emitting portions 132 are sequentially selected row by row by the driver circuit 232, whereby the transistors 431 are turned on and a data signal is written to the nodes 435.

When the transistors 431 are turned off, the light-emitting portions 132 in which the data has been written to the nodes 435 are brought into a holding state. Furthermore, the amount of current flowing between the source electrode and the drain electrode of the transistor 242 is controlled in accordance with the potential of the data written to the node 435. The light-emitting element 125 emits light with luminance corresponding to the amount of flowing current. This operation is sequentially performed row by row; thus, an image is displayed.

Note that a display element other than the light-emitting element 125 can be used. For example, a liquid crystal element, an electrophoretic element, an electronic ink, an electrowetting element, a micro electro mechanical system (MEMS), a digital micromirror device (DMD), a digital micro shutter (DMS), or an interferometric modulator (IMOD) element can be used as the display element.

### <Example of Manufacturing Process of Light-Emitting Device>

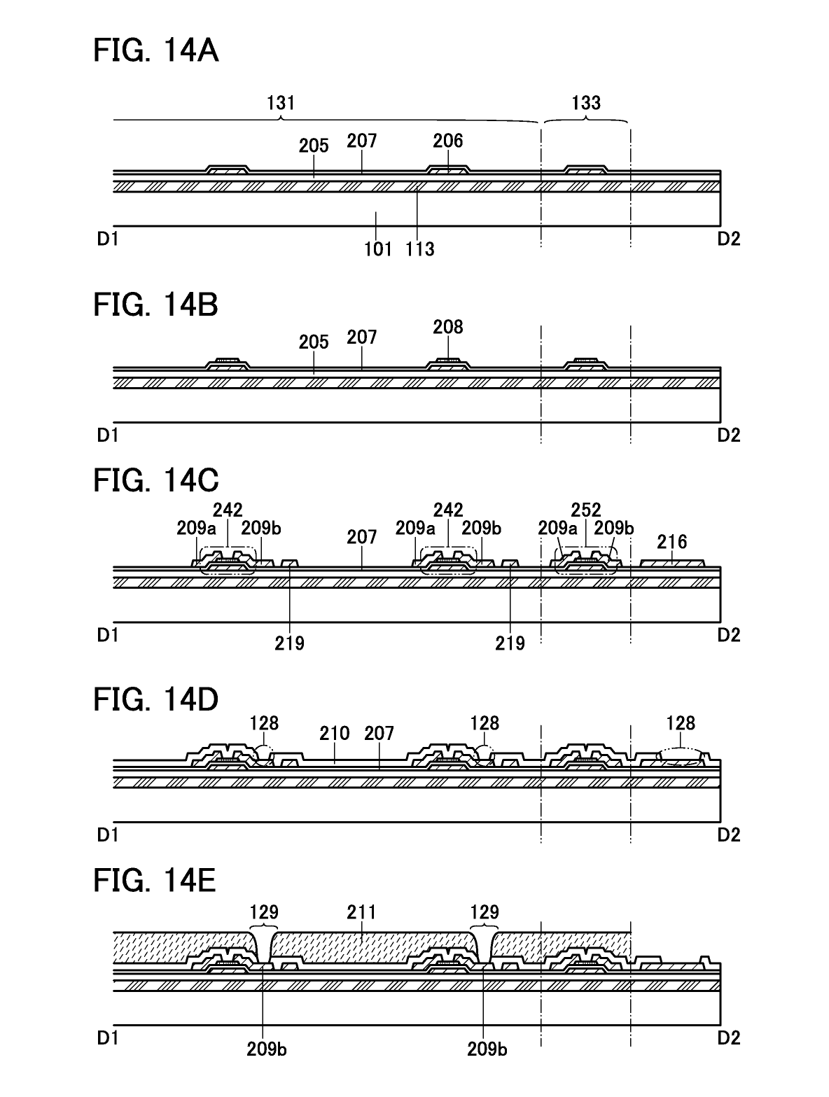

Next, an example of a manufacturing process of the light-emitting device 100 is described with reference to FIGS. 14A to 14E, FIGS. 15A to 15D, FIGS. 16A and 16B, FIGS. 17A and 17B, FIGS. 18A and 18B, FIGS. 19A to 19C, FIGS. 20A and 20B, FIGS. 21A and 21B, and FIGS. 22A and 22B. FIGS. 14A to 22B are cross-sectional views of a portion denoted by the dashed-dotted line D1-D2 in FIG. 12A.

### [Formation of Separation Layer 113]

First, a separation layer 113 is formed over an element formation substrate 101 (see FIG. 14A). Note that the element formation substrate 101 may be a glass substrate, a quartz substrate, a sapphire substrate, a ceramic substrate, a metal substrate, or the like. Alternatively, a plastic substrate having heat resistance to the processing temperature of this embodiment may be used.

As the glass substrate, a glass material such as aluminosilicate glass, aluminoborosilicate glass, or barium borosilicate glass is used, for example. Note that by containing a large amount of barium oxide (BaO), a glass substrate which is heat-resistant and more practical can be obtained. Alternatively, crystallized glass or the like may be used.

The separation layer 113 can be formed using an element selected from tungsten, molybdenum, titanium, tantalum, niobium, nickel, cobalt, zirconium, ruthenium, rhodium, palladium, osmium, iridium, and silicon; an alloy material containing any of the elements; or a compound material containing any of the elements. The separation layer 113 can also be formed to have a single-layer structure or a stacked-layer structure using any of the materials. Note that the crystalline structure of the separation layer 113 may be amorphous, microcrystalline, or polycrystalline. The separation layer 113 can also be formed using a metal oxide such as aluminum oxide, gallium oxide, zinc oxide, titanium dioxide, indium oxide, indium tin oxide, indium zinc oxide, or InGaZnO (IGZO).

The separation layer 113 can be formed by a sputtering method, a CVD method, a coating method, a printing method, or the like. Note that the coating method includes a spin coating method, a droplet discharge method, and a dispensing method.

In the case where the separation layer 113 has a single-layer structure, the separation layer 113 is preferably formed using tungsten, molybdenum, or a tungsten-molybdenum alloy. Alternatively, the separation layer 113 is preferably formed using an oxide or oxynitride of tungsten, an oxide or oxynitride of molybdenum, or an oxide or oxynitride of a tungsten-molybdenum alloy.

In the case where the separation layer 113 has a stacked-layer structure including, for example, a layer containing tungsten and a layer containing an oxide of tungsten, the layer containing an oxide of tungsten may be formed as follows: the layer containing tungsten is formed first and then an oxide insulating layer is formed in contact therewith, so that the layer containing an oxide of tungsten is formed at the interface between the layer containing tungsten and the oxide insulating layer. Alternatively, the layer containing an oxide of tungsten may be formed by performing thermal oxidation treatment, oxygen plasma treatment, treatment with a highly oxidizing solution such as ozone water, or the like on the surface of the layer containing tungsten.

In this embodiment, a glass substrate is used as the element formation substrate 101. The separation layer 113 is formed of tungsten over the element formation substrate 101 by a sputtering method.

### [Formation of Insulating Layer 205]

Next, the insulating layer 205 is formed as a base layer over the separation layer 113 (see FIG. 14A). The insulating layer 205 is preferably formed as a single layer or a multilayer using any of silicon oxide, silicon nitride, silicon oxynitride, silicon nitride oxide, aluminum oxide, aluminum oxynitride, aluminum nitride oxide, or the like. The insulating layer 205 may have, for example, a two-layer structure of silicon oxide and silicon nitride or a five-layer structure in which materials selected from the above are combined. The insulating layer 205 can be formed by a sputtering method, a CVD method, a thermal oxidation method, a coating method, a printing method, or the like.

The thickness of the insulating layer 205 may be greater than or equal to 30 nm and less than or equal to 500 nm, preferably greater than or equal to 50 nm and less than or equal to 400 nm.

The insulating layer 205 can prevent or reduce diffusion of impurity elements from the element formation substrate 101, the separation layer 113, or the like. Even after the element formation substrate 101 is replaced by the substrate 111, the insulating layer 205 can prevent or reduce diffusion of impurity elements into the light-emitting element 125 from the substrate 111, the bonding layer 112, or the like. In this embodiment, the insulating layer 205 is formed by stacking a 200-nm-thick silicon oxynitride film and a 50-nm-thick silicon nitride oxide film by a plasma CVD method.

### [Formation of Gate Electrode 206]

Next, the gate electrode 206 is formed over the insulating layer 205 (see FIG. 14A). The gate electrode 206 can be formed using a metal element selected from aluminum, chromium, copper, tantalum, titanium, molybdenum, and tungsten; an alloy containing any of these metal elements as a component; an alloy containing any of these metal elements in combination; or the like. Furthermore, one or more metal elements selected from manganese and zirconium may be used. The gate electrode 206 may have a single-layer structure or a stacked-layer structure of two or more layers. For example, a single-layer structure of an aluminum film containing silicon, a two-layer structure in which an aluminum film is stacked over a titanium film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a two-layer structure in which a copper film is stacked over a titanium film, and a three-layer structure in which a titanium film, an aluminum film, and a titanium film are stacked in this order can be given. Alternatively, an alloy film or a nitride film in which aluminum and one or more elements selected from titanium, tantalum, tungsten, molybdenum, chromium, neodymium, and scandium are contained may be used.

The gate electrode 206 can be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. It is also possible to have a stacked-layer structure formed using the above light-transmitting conductive material and the above metal element.

First, a conductive film to be the gate electrode 206 later is stacked over the insulating layer 205 by a sputtering method, a CVD method, an evaporation method, or the like, and a resist mask is formed over the conductive film by a photolithography process. Next, part of the conductive film to be the gate electrode 206 is etched with the use of the resist mask to form the gate electrode 206. At the same time, a wiring and another electrode can be formed.

The conductive film may be etched by a dry etching method, a wet etching method, or both a dry etching method and a wet etching method. Note that in the case where the conductive film is etched by a dry etching method, ashing treatment may be performed before the resist mask is removed, whereby the resist mask can be easily removed using a stripper.

Note that the gate electrode 206 may be formed by an electrolytic plating method, a printing method, an ink jet method, or the like instead of the above formation method.

The thickness of the conductive film, i.e. the gate electrode 206 is greater than or equal to 5 nm and less than or equal to 500 nm, preferably greater than or equal to 10 nm and less than or equal to 300 nm, further preferably greater than or equal to 10 nm and less than or equal to 200 nm.

The gate electrode 206 may be formed using a light-blocking conductive material, whereby external light can hardly reach the semiconductor layer 208 from the gate electrode 206 side. As a result, a variation in electrical characteristics of the transistor due to light irradiation can be suppressed.

### [Formation of Gate Insulating Layer 207]

Next, the gate insulating layer 207 is formed (see FIG. 14A). The gate insulating layer 207 can be formed to have a single-layer structure or a stacked-layer structure using, for example, any of silicon oxide, silicon oxynitride, silicon nitride oxide, silicon nitride, aluminum oxide, a mixture of aluminum oxide and silicon oxide, hafnium oxide, gallium oxide, Ga—Zn-based metal oxide, silicon nitride, and the like.

The gate insulating layer 207 may be formed using a high-k material such as hafnium silicate (HfSiOₓ), hafnium silicate to which nitrogen is added (HfSiₓO_{y}N_{z}), hafnium aluminate to which nitrogen is added (HfAlₓO_{y}N_{z}), hafnium oxide, or yttrium oxide, so that gate leakage current of the transistor can be reduced. For example, a stacked layer of silicon oxynitride and hafnium oxide may be used.

The thickness of the gate insulating layer 207 is preferably greater than or equal to 5 nm and less than or equal to 400 nm, further preferably greater than or equal to 10 nm and less than or equal to 300 nm, still further preferably greater than or equal to 50 nm and less than or equal to 250 nm.

The gate insulating layer 207 can be formed by a sputtering method, a CVD method, an evaporation method, or the like.

In the case where a silicon oxide film, a silicon oxynitride film, or a silicon nitride oxide film is formed as the gate insulating layer 207, a deposition gas containing silicon and an oxidizing gas are preferably used as a source gas. Typical examples of the deposition gas containing silicon include silane, disilane, trisilane, and silane fluoride. As the oxidizing gas, oxygen, ozone, dinitrogen monoxide, and nitrogen dioxide can be given as examples.

The gate insulating layer 207 can have a stacked-layer structure in which a nitride insulating layer and an oxide insulating layer are stacked in this order from the gate electrode 206 side. When the nitride insulating layer is provided on the gate electrode 206 side, hydrogen, nitrogen, an alkali metal, an alkaline earth metal, or the like can be prevented from moving from the gate electrode 206 side to the semiconductor layer 208. Note that nitrogen, an alkali metal, an alkaline earth metal, or the like generally serves as an impurity element of a semiconductor. In addition, hydrogen serves as an impurity element of an oxide semiconductor. Thus, an “impurity” in this specification and the like includes hydrogen, nitrogen, an alkali metal, an alkaline earth metal, or the like.

In the case where an oxide semiconductor is used for the semiconductor layer 208, the density of defect states at the interface between the gate insulating layer 207 and the semiconductor layer 208 can be reduced by providing the oxide insulating layer on the semiconductor layer 208 side. Consequently, a transistor whose electrical characteristics are hardly degraded can be obtained. Note that in the case where an oxide semiconductor is used for the semiconductor layer 208, an oxide insulating layer containing oxygen in a proportion higher than that in the stoichiometric composition is preferably formed as the oxide insulating layer. This is because the density of defect states at the interface between the gate insulating layer 207 and the semiconductor layer 208 can be further reduced.

In the case where the gate insulating layer 207 is a stacked layer of a nitride insulating layer and an oxide insulating layer as described above, it is preferable that the nitride insulating layer be thicker than the oxide insulating layer.

The nitride insulating layer has a dielectric constant higher than that of the oxide insulating layer; therefore, an electric field generated from the gate electrode 206 can be efficiently transmitted to the semiconductor layer 208 even when the gate insulating layer 207 has a large thickness. When the gate insulating layer 207 has a large total thickness, the withstand voltage of the gate insulating layer 207 can be increased. Thus, the reliability of the light-emitting device can be improved.

The gate insulating layer 207 can have a stacked-layer structure in which a first nitride insulating layer with few defects, a second nitride insulating layer with a high blocking property against hydrogen, and an oxide insulating layer are stacked in that order from the gate electrode 206 side. When the first nitride insulating layer with few defects is used in the gate insulating layer 207, the withstand voltage of the gate insulating layer 207 can be improved. Particularly when an oxide semiconductor is used for the semiconductor layer 208, the use of the second nitride insulating layer with a high blocking property against hydrogen in the gate insulating layer 207 makes it possible to prevent hydrogen contained in the gate electrode 206 and the first nitride insulating layer from moving to the semiconductor layer 208.

An example of a method for forming the first and second nitride insulating layers is described below. First, a silicon nitride film with few defects is formed as the first nitride insulating layer by a plasma CVD method in which a mixed gas of silane, nitrogen, and ammonia is used as a source gas. Next, a silicon nitride film in which the hydrogen concentration is low and hydrogen can be blocked is formed as the second nitride insulating layer by switching the source gas to a mixed gas of silane and nitrogen. By such a formation method, the gate insulating layer 207 in which nitride insulating layers with few defects and a blocking property against hydrogen are stacked can be formed.

The gate insulating layer 207 can have a stacked-layer structure in which a third nitride insulating layer with a high blocking property against an impurity, the first nitride insulating layer with few defects, the second nitride insulating layer with a high blocking property against hydrogen, and the oxide insulating layer are stacked in that order from the gate electrode 206 side. When the third nitride insulating layer with a high blocking property against an impurity is provided in the gate insulating layer 207, hydrogen, nitrogen, alkali metal, alkaline earth metal, or the like, can be prevented from moving from the gate electrode 206 to the semiconductor layer 208.

An example of a method for forming the first to third nitride insulating layers is described below. First, a silicon nitride film with a high blocking property against an impurity is formed as the third nitride insulating layer by a plasma CVD method in which a mixed gas of silane, nitrogen, and ammonia is used as a source gas. Next, a silicon nitride film with few defects is formed as the first nitride insulating layer by increasing the flow rate of ammonia. Next, a silicon nitride film in which the hydrogen concentration is low and hydrogen can be blocked is formed as the second nitride insulating layer by switching the source gas to a mixed gas of silane and nitrogen. By such a formation method, the gate insulating layer 207 in which nitride insulating layers with few defects and a blocking property against an impurity are stacked can be formed.

Moreover, in the case of forming a gallium oxide film as the gate insulating layer 207, a metal organic chemical vapor deposition (MOCVD) method can be employed.

Note that the threshold voltage of a transistor can be changed by stacking the semiconductor layer 208 in which a channel of the transistor is formed and an insulating layer containing hafnium oxide with an oxide insulating layer provided therebetween and injecting electrons into the insulating layer containing hafnium oxide.

### [Formation of Semiconductor Layer 208]

The semiconductor layer 208 can be formed using an amorphous semiconductor, a microcrystalline semiconductor, a polycrystalline semiconductor, or the like. For example, amorphous silicon or microcrystalline germanium can be used. Alternatively, a compound semiconductor such as silicon carbide, gallium arsenide, an oxide semiconductor, or a nitride semiconductor; an organic semiconductor; or the like can be used.

The semiconductor layer 208 can be formed by a CVD method such as a plasma CVD method, an LPCVD method, a metal CVD method, or an MOCVD method, an ALD method, a sputtering method, an evaporation method, or the like. Note that a formation surface can be less damaged when the semiconductor layer 208 is formed by a method such as an MOCVD method without plasma.

The thickness of the semiconductor layer 208 is greater than or equal to 3 nm and less than or equal to 200 nm, preferably greater than or equal to 3 nm and less than or equal to 100 nm, further preferably greater than or equal to 3 nm and less than or equal to 50 nm. In this embodiment, as the semiconductor layer 208, an oxide semiconductor film with a thickness of 30 nm is formed by a sputtering method.

Next, a resist mask is formed over the oxide semiconductor film, and part of the oxide semiconductor film is selectively etched using the resist mask to form the semiconductor layer 208. The resist mask can be formed by a photolithography method, a printing method, an ink jet method, or the like as appropriate. Formation of the resist mask by an ink jet method needs no photomask; thus, manufacturing cost can be reduced.

Note that the etching of the oxide semiconductor film may be performed by either one or both of a dry etching method and a wet etching method. After the etching of the oxide semiconductor film, the resist mask is removed (see FIG. 14B).

### <Structure of Oxide Semiconductor>

A structure of an oxide semiconductor is described below.

An oxide semiconductor is classified into, for example, a non-single-crystal oxide semiconductor and a single crystal oxide semiconductor. Alternatively, an oxide semiconductor is classified into, for example, a crystalline oxide semiconductor and an amorphous oxide semiconductor.

Examples of a non-single-crystal oxide semiconductor include a c-axis aligned crystalline oxide semiconductor (CAAC-OS), a polycrystalline oxide semiconductor, a microcrystalline oxide semiconductor, and an amorphous oxide semiconductor. In addition, examples of a crystalline oxide semiconductor include a single crystal oxide semiconductor, a CAAC-OS, a polycrystalline oxide semiconductor, and a microcrystalline oxide semiconductor.

First, a CAAC-OS is described.

A CAAC-OS is one of oxide semiconductors having a plurality of c-axis aligned crystal parts (also referred to as pellets).

In a combined analysis image (also referred to as a high-resolution TEM image) of a bright-field image and a diffraction pattern of a CAAC-OS, which is obtained using a transmission electron microscope (TEM), a plurality of pellets can be observed. However, in the high-resolution TEM image, a boundary between pellets, that is, a grain boundary is not clearly observed. Thus, in the CAAC-OS, a reduction in electron mobility due to the grain boundary is less likely to occur.

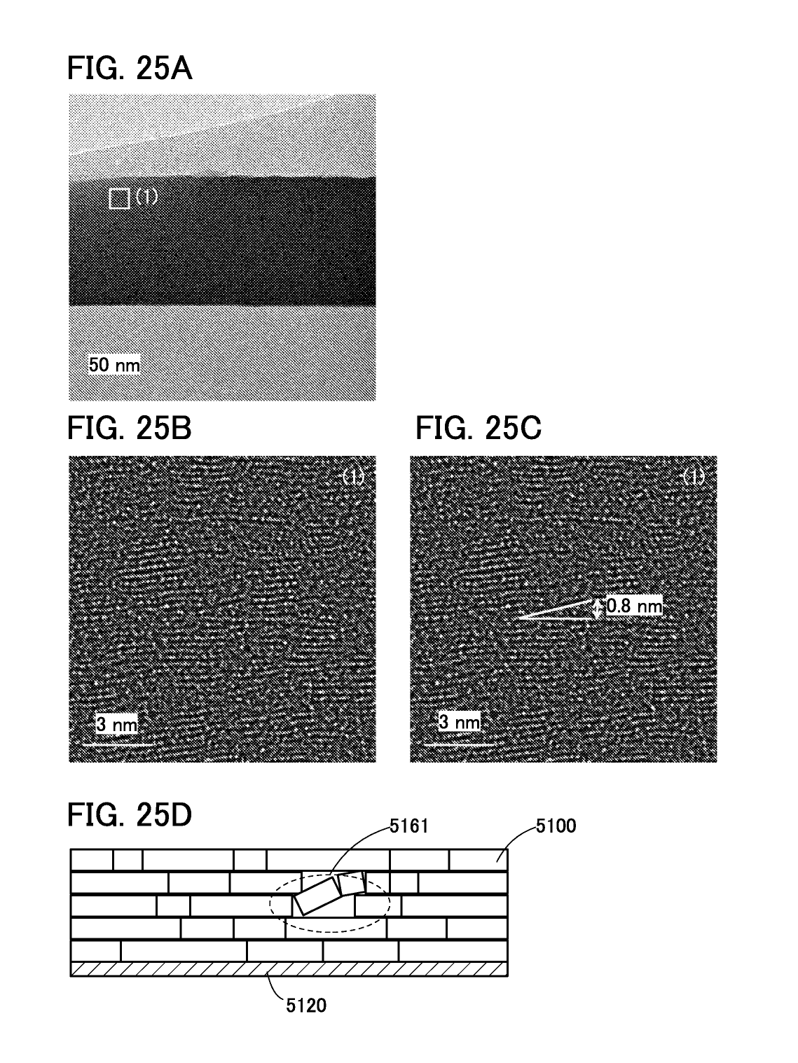

FIG. 25A shows an example of a high-resolution TEM image of a cross section of the CAAC-OS which is obtained from a direction substantially parallel to the sample surface. Here, the TEM image is obtained with a spherical aberration corrector function. The high-resolution TEM image obtained with a spherical aberration corrector function is particularly referred to as a Cs-corrected high-resolution TEM image in the following description. Note that the Cs-corrected high-resolution TEM image can be obtained with, for example, an atomic resolution analytical electron microscope JEM-ARM200F manufactured by JEOL Ltd.

FIG. 25B is an enlarged Cs-corrected high-resolution TEM image of a region (1) in FIG. 25A. FIG. 25B shows that metal atoms are arranged in a layered manner in a pellet. Each metal atom layer has a configuration reflecting unevenness of a surface over which the CAAC-OS is formed (hereinafter, the surface is referred to as a formation surface) or a top surface of the CAAC-OS, and is arranged parallel to the formation surface or the top surface of the CAAC-OS.

As shown in FIG. 25B, the CAAC-OS has a characteristic atomic arrangement. The characteristic atomic arrangement is denoted by an auxiliary line in FIG. 25C. FIGS. 25B and 25C prove that the size of a pellet is approximately 1 nm to 3 nm, and the size of a space caused by tilt of the pellets is approximately 0.8 nm. Therefore, the pellet can also be referred to as a nanocrystal (nc).

Here, according to the Cs-corrected high-resolution TEM images, the schematic arrangement of pellets 5100 of a CAAC-OS over a substrate 5120 is illustrated by such a structure in which bricks or blocks are stacked (see FIG. 25D). The part in which the pellets are tilted as observed in FIG. 25C corresponds to a region 5161 shown in FIG. 25D.

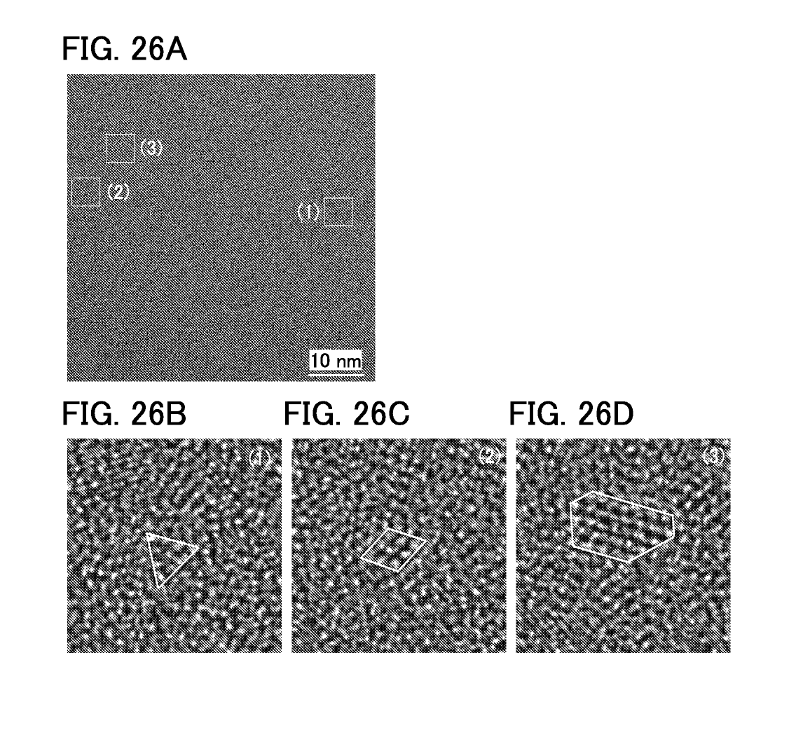

For example, as shown in FIG. 26A, a Cs-corrected high-resolution TEM image of a plane of the CAAC-OS obtained from a direction substantially perpendicular to the sample surface is observed. FIGS. 26B, 26C, and 26D are enlarged Cs-corrected high-resolution TEM images of regions (1), (2), and (3) in FIG. 26A, respectively. FIGS. 26B, 26C, and 26D indicate that metal atoms are arranged in a triangular, quadrangular, or hexagonal configuration in a pellet. However, there is no regularity of arrangement of metal atoms between different pellets.

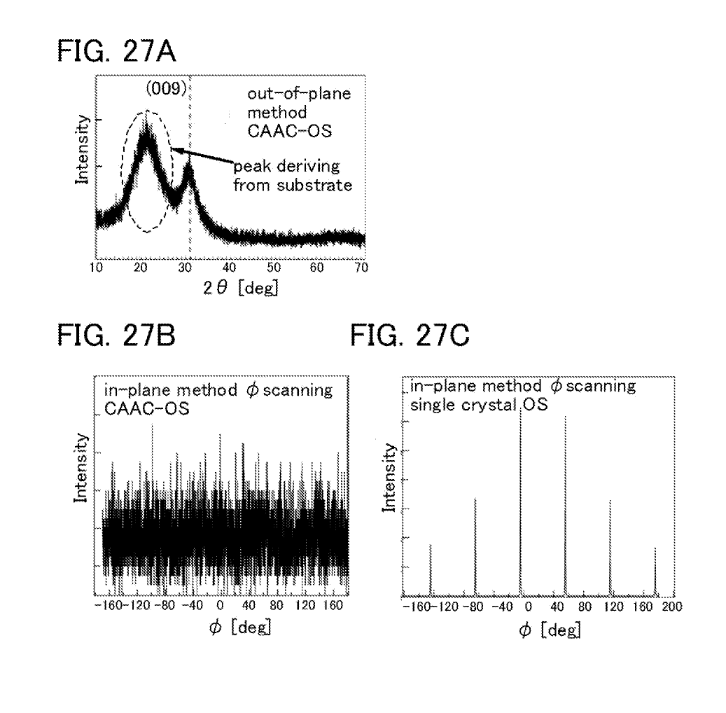

For example, when the structure of a CAAC-OS including an InGaZnO₄ crystal is analyzed by an out-of-plane method using an X-ray diffraction (XRD) apparatus, a peak appears at a diffraction angle (2θ) of around 31° as shown in FIG. 27A. This peak is derived from the (009) plane of the InGaZnO₄ crystal, which indicates that crystals in the CAAC-OS have c-axis alignment, and that the c-axes are aligned in a direction substantially perpendicular to the formation surface or the top surface of the CAAC-OS.

Note that in structural analysis of the CAAC-OS including an InGaZnO₄ crystal by an out-of-plane method, another peak may appear when 2θ is around 36°, in addition to the peak at 2θ of around 31°. The peak at 2θ of around 36° indicates that a crystal having no c-axis alignment is included in part of the CAAC-OS. It is preferable that in the CAAC-OS, a peak appear when 20 is around 31° and that a peak not appear when 2θ is around 36°.

On the other hand, in structural analysis of the CAAC-OS by an in-plane method in which an X-ray is incident on a sample in a direction substantially perpendicular to the c-axis, a peak appears when 2θ is around 56°. This peak is attributed to the (110) plane of the InGaZnO₄ crystal. In the case of the CAAC-OS, when analysis (φ scan) is performed with 20 fixed at around 56° and with the sample rotated using a normal vector of the sample surface as an axis (0 axis), as shown in FIG. 27B, a peak is not clearly observed. In contrast, in the case of a single crystal oxide semiconductor of InGaZnO₄, when φ scan is performed with 2θ fixed at around 56°, as shown in FIG. 27C, six peaks which are derived from crystal planes equivalent to the (110) plane are observed. Accordingly, the structural analysis using XRD shows that the directions of a-axes and b-axes are different in the CAAC-OS.

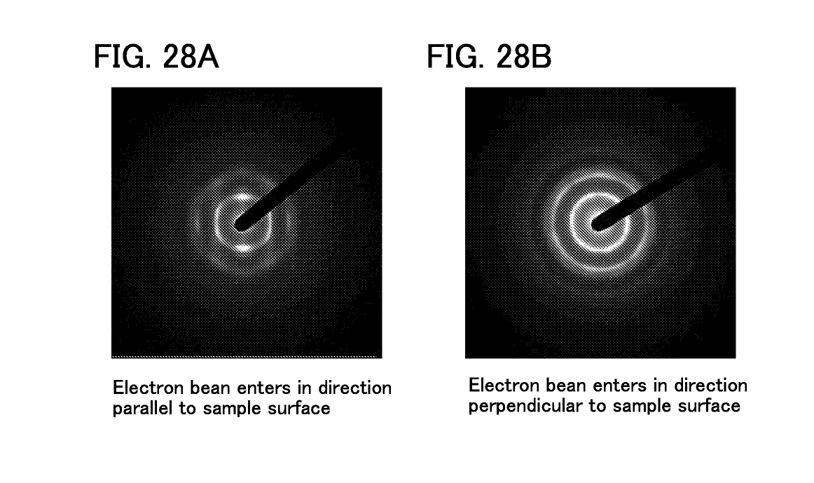

Next, FIG. 28A shows a diffraction pattern (also referred to as a selected-area transmission electron diffraction pattern) obtained in such a manner that an electron beam with a probe diameter of 300 nm is incident on an In—Ga—Zn oxide that is a CAAC-OS in a direction parallel to the sample surface. As shown in FIG. 28A, for example, spots derived from the (009) plane of an InGaZnO₄ crystal are observed. Thus, the electron diffraction also indicates that pellets included in the CAAC-OS have c-axis alignment and that the c-axes are aligned in a direction substantially perpendicular to the formation surface or the top surface of the CAAC-OS. Meanwhile, FIG. 28B shows a diffraction pattern obtained in such a manner that an electron beam with a probe diameter of 300 nm is incident on the same sample in a direction perpendicular to the sample surface. As shown in FIG. 28B, a ring-like diffraction pattern is observed. Thus, the electron diffraction also indicates that the a-axes and b-axes of the pellets included in the CAAC-OS do not have regular alignment. The first ring in FIG. 28B is considered to be derived from the (010) plane, the (100) plane, and the like of the InGaZnO₄ crystal. The second ring in FIG. 28B is considered to be derived from the (110) plane and the like.

Since the c-axes of the pellets (nanocrystals) are aligned in a direction substantially perpendicular to the formation surface or the top surface in the above manner, the CAAC-OS can also be referred to as an oxide semiconductor including c-axis aligned nanocrystals (CANC).

The CAAC-OS is an oxide semiconductor with a low impurity concentration. The impurity means an element other than the main components of the oxide semiconductor, such as hydrogen, carbon, silicon, or a transition metal element. An element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity. Additionally, the impurity contained in the oxide semiconductor might serve as a carrier trap or a carrier generation source.

Moreover, the CAAC-OS is an oxide semiconductor having a low density of defect states. For example, oxygen vacancies in the oxide semiconductor serve as carrier traps or serve as carrier generation sources when hydrogen is captured therein.

In a transistor using the CAAC-OS, change in electrical characteristics due to irradiation with visible light or ultraviolet light is small.

Next, a microcrystalline oxide semiconductor is described.

A microcrystalline oxide semiconductor has a region in which a crystal part is observed and a region in which a crystal part is not clearly observed in a high-resolution TEM image. In most cases, the size of a crystal part included in the microcrystalline oxide semiconductor is greater than or equal to 1 nm and less than or equal to 100 nm, or greater than or equal to 1 nm and less than or equal to 10 nm. An oxide semiconductor including a nanocrystal that is a microcrystal with a size greater than or equal to 1 nm and less than or equal to 10 nm, or a size greater than or equal to 1 nm and less than or equal to 3 nm is specifically referred to as a nanocrystalline oxide semiconductor (nc-OS). In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not ordered. Accordingly, the nc-OS cannot be distinguished from an amorphous oxide semiconductor, depending on an analysis method. For example, when the nc-OS is subjected to structural analysis by an out-of-plane method with an XRD apparatus using an X-ray having a diameter larger than the size of a pellet, a peak which shows a crystal plane does not appear. Furthermore, a diffraction pattern like a halo pattern is observed when the nc-OS is subjected to electron diffraction using an electron beam with a probe diameter (e.g., 50 nm or larger) that is larger than the size of a pellet (the electron diffraction is also referred to as selected-area electron diffraction). Meanwhile, spots appear in a nanobeam electron diffraction pattern of the nc-OS when an electron beam having a probe diameter close to or smaller than the size of a pellet is applied. Moreover, in a nanobeam electron diffraction pattern of the nc-OS, regions with high luminance in a circular (ring) pattern are shown in some cases. Also in a nanobeam electron diffraction pattern of the nc-OS, a plurality of spots are shown in a ring-like region in some cases.

Since there is no regularity of crystal orientation between the pellets (nanocrystals) as mentioned above, the nc-OS can also be referred to as an oxide semiconductor including non-aligned nanocrystals (NANC).

The nc-OS is an oxide semiconductor that has high regularity as compared with an amorphous oxide semiconductor. Therefore, the nc-OS is likely to have a lower density of defect states than an amorphous oxide semiconductor. Note that there is no regularity of crystal orientation between different pellets in the nc-OS. Therefore, the nc-OS has a higher density of defect states than the CAAC-OS.

Next, an amorphous oxide semiconductor is described.

The amorphous oxide semiconductor is an oxide semiconductor having disordered atomic arrangement and no crystal part and exemplified by an oxide semiconductor which exists in an amorphous state as quartz.

In a high-resolution TEM image of the amorphous oxide semiconductor, crystal parts cannot be found.

When the amorphous oxide semiconductor is subjected to structural analysis by an out-of-plane method with an XRD apparatus, a peak which shows a crystal plane does not appear. A halo pattern is observed when the amorphous oxide semiconductor is subjected to electron diffraction. Furthermore, a spot is not observed and a halo pattern appears when the amorphous oxide semiconductor is subjected to nanobeam electron diffraction.

There are various understandings of an amorphous structure. For example, a structure whose atomic arrangement does not have ordering at all is called a completely amorphous structure. Meanwhile, a structure which has ordering until the nearest neighbor atomic distance or the second-nearest neighbor atomic distance but does not have long-range ordering is also called an amorphous structure. Therefore, the strictest definition does not permit an oxide semiconductor to be called an amorphous oxide semiconductor as long as even a negligible degree of ordering is present in an atomic arrangement. At least an oxide semiconductor having long-term ordering cannot be called an amorphous oxide semiconductor. Accordingly, because of the presence of crystal part, for example, a CAAC-OS and an nc-OS cannot be called an amorphous oxide semiconductor or a completely amorphous oxide semiconductor.

Note that an oxide semiconductor may have a structure having physical properties intermediate between the nc-OS and the amorphous oxide semiconductor. The oxide semiconductor having such a structure is specifically referred to as an amorphous-like oxide semiconductor (a-like OS).

In a high-resolution TEM image of the a-like OS, a void may be observed. Furthermore, in the high-resolution TEM image, there are a region where a crystal part is clearly observed and a region where a crystal part is not observed.

A difference in effect of electron irradiation between structures of an oxide semiconductor is described below.

An a-like OS, an nc-OS, and a CAAC-OS are prepared. Each of the samples is an In—Ga—Zn oxide.

First, a high-resolution cross-sectional TEM image of each sample is obtained. The high-resolution cross-sectional TEM images show that all the samples have crystal parts.

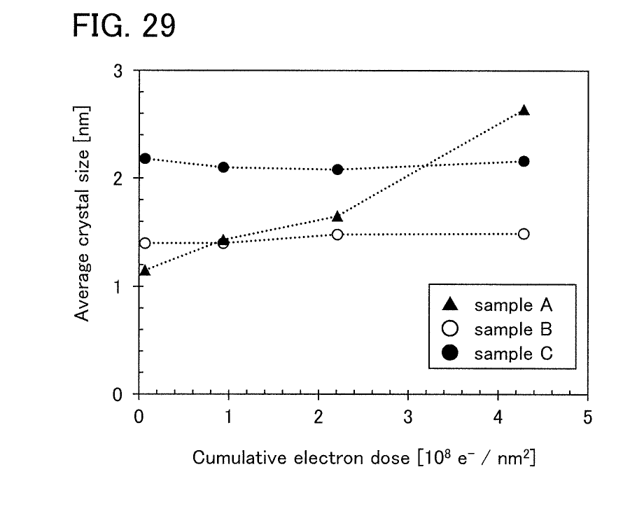

Then, the size of the crystal part of each sample is measured. FIG. 29 shows the change in the average size of crystal parts (at 22 points to 45 points) in each sample. FIG. 29 indicates that the crystal part size in the a-like OS increases with an increase in the cumulative electron dose. Specifically, as shown by (1) in FIG. 29, a crystal part of approximately 1.2 nm at the start of TEM observation (the crystal part is also referred to as an initial nucleus) grows to a size of approximately 2.6 nm at a cumulative electron dose of 4.2×10⁸ e⁻/nm². In contrast, the crystal part size in the nc-OS and the CAAC-OS shows little change from the start of electron irradiation to a cumulative electron dose of 4.2×10⁸ e⁻/nm² regardless of the cumulative electron dose. Specifically, as shown by (2) in FIG. 29, the average crystal size is approximately 1.4 nm regardless of the observation time by TEM. Furthermore, as shown by (3) in FIG. 29, the average crystal size is approximately 2.1 nm regardless of the observation time by TEM.

In this manner, growth of the crystal part occurs due to the crystallization of the a-like OS, which is induced by a slight amount of electron beam employed in the TEM observation. In contrast, in the nc-OS and the CAAC-OS that have good quality, crystallization hardly occurs by a slight amount of electron beam used for TEM observation.

Note that the crystal part size in the a-like OS and the nc-OS can be measured using high-resolution TEM images. For example, an InGaZnO₄ crystal has a layered structure in which two Ga—Zn—O layers are included between In—O layers. A unit cell of the InGaZnO₄ crystal has a structure in which nine layers including three In—O layers and six Ga—Zn—O layers are stacked in the c-axis direction. Accordingly, the distance between the adjacent layers is equivalent to the lattice spacing on the (009) plane (also referred to as d value). The value is calculated to be 0.29 nm from crystal structural analysis. Thus, focusing on lattice fringes in the high-resolution TEM image, each of lattice fringes in which the lattice spacing therebetween is greater than or equal to 0.28 nm and less than or equal to 0.30 nm corresponds to the a-b plane of the InGaZnO₄ crystal.

Furthermore, the density of an oxide semiconductor varies depending on the structure in some cases. For example, when the composition of an oxide semiconductor is determined, the structure of the oxide semiconductor can be expected by comparing the density of the oxide semiconductor with the density of a single crystal oxide semiconductor having the same composition as the oxide semiconductor. For example, the density of the a-like OS is higher than or equal to 78.6% and lower than 92.3% of the density of the single crystal oxide semiconductor having the same composition. For example, the density of each of the nc-OS and the CAAC-OS is higher than or equal to 92.3% and lower than 100% of the density of the single crystal oxide semiconductor having the same composition. Note that it is difficult to deposit an oxide semiconductor having a density of lower than 78% of the density of the single crystal oxide semiconductor.

Specific examples of the above description are given. For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that there is a possibility that an oxide semiconductor having a certain composition cannot exist in a single crystal structure. In that case, single crystal oxide semiconductors with different compositions are combined at an adequate ratio, which makes it possible to calculate density equivalent to that of a single crystal oxide semiconductor with the desired composition. The density of a single crystal oxide semiconductor having the desired composition can be calculated using a weighted average according to the combination ratio of the single crystal oxide semiconductors with different compositions. Note that it is preferable to use as few kinds of single crystal oxide semiconductors as possible to calculate the density.

Note that an oxide semiconductor may be a stacked film including two or more films of an amorphous oxide semiconductor, an a-like OS, a microcrystalline oxide semiconductor, and a CAAC-OS, for example.

An oxide semiconductor having a low impurity concentration and a low density of defect states (a small number of oxygen vacancies) can have low carrier density. Therefore, such an oxide semiconductor is referred to as a highly purified intrinsic or substantially highly purified intrinsic oxide semiconductor. A CAAC-OS and an nc-OS have a low impurity concentration and a low density of defect states as compared to an a-like OS and an amorphous oxide semiconductor. That is, a CAAC-OS and an nc-OS are likely to be highly purified intrinsic or substantially highly purified intrinsic oxide semiconductors. Thus, a transistor including a CAAC-OS or an nc-OS rarely has negative threshold voltage (is rarely normally on). The highly purified intrinsic or substantially highly purified intrinsic oxide semiconductor has few carrier traps. Therefore, a transistor including a CAAC-OS or an nc-OS has small variation in electrical characteristics and high reliability. An electric charge trapped by the carrier traps in the oxide semiconductor takes a long time to be released. The trapped electric charge may behave like a fixed electric charge. Thus, the transistor which includes the oxide semiconductor having a high impurity concentration and a high density of defect states might have unstable electrical characteristics.

### <Deposition Model>

Examples of deposition models of a CAAC-OS and an nc-OS are described below.

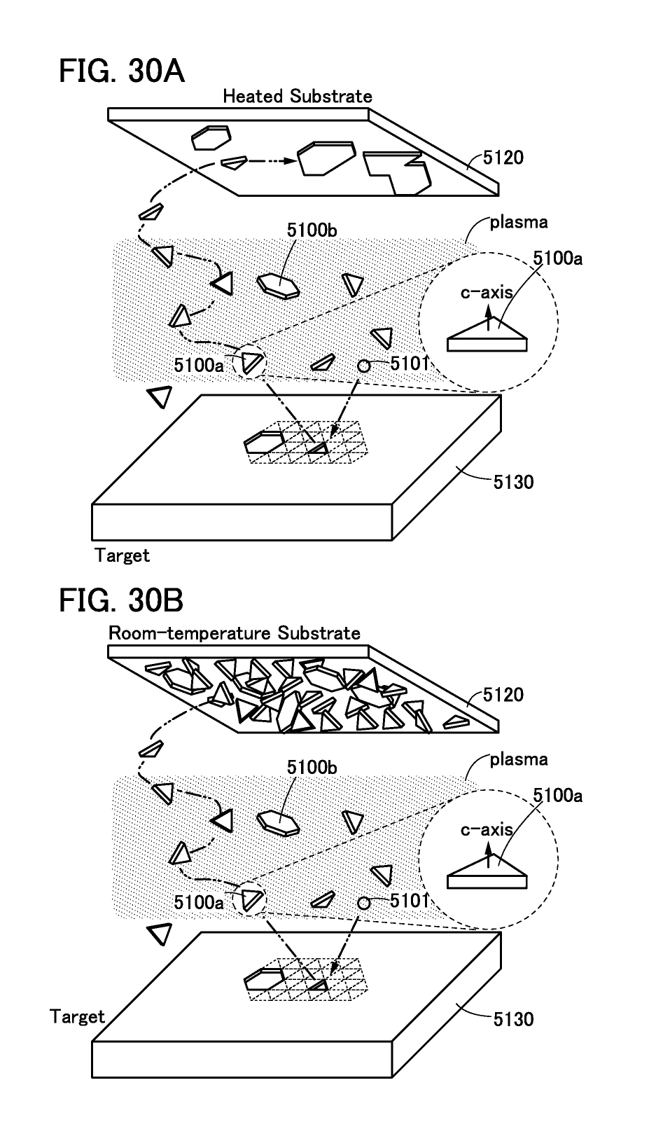

FIG. 30A is a schematic view of the inside of a deposition chamber where a CAAC-OS is deposited by a sputtering method.

A target 5130 is attached to a backing plate (not illustrated). A plurality of magnets are provided to face the target 5130 with the backing plate positioned therebetween. The plurality of magnets generates a magnetic field. A sputtering method in which the disposition rate is increased by utilizing a magnetic field of magnets is referred to as a magnetron sputtering method.

The target 5130 has a polycrystalline structure in which a cleavage plane exists in at least one crystal grain.

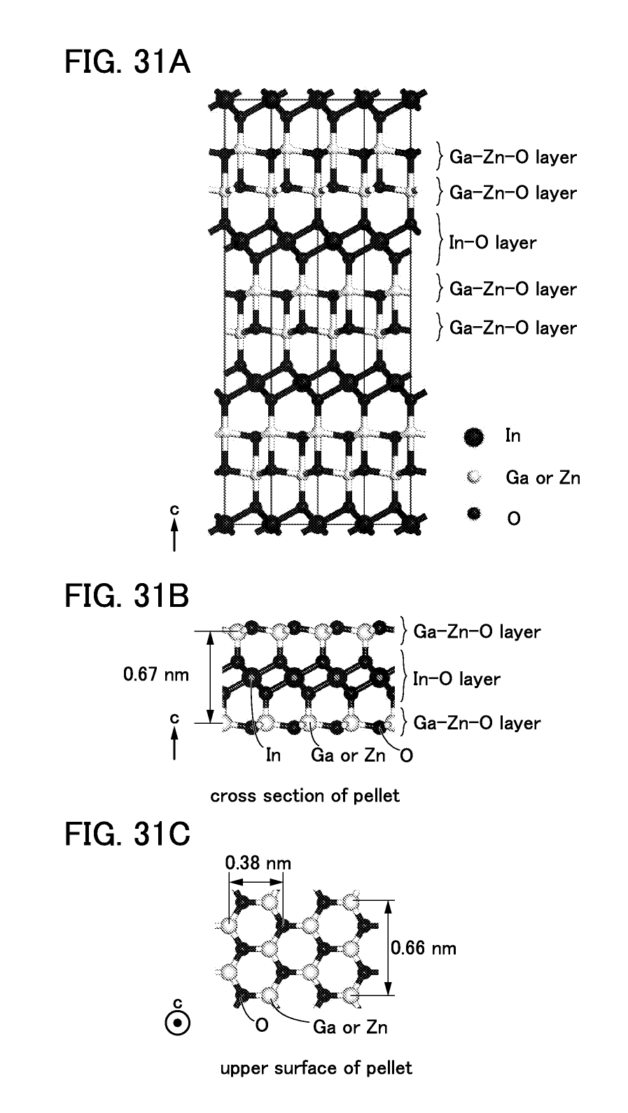

A cleavage plane of the target 5130 including an In—Ga—Zn oxide is described as an example. FIG. 31A shows a structure of an InGaZnO₄ crystal included in the target 5130. Note that FIG. 31A shows a structure of the case where the InGaZnO₄ crystal is observed from a direction parallel to the b-axis when the c-axis is in an upward direction.

FIG. 31A indicates that oxygen atoms in a Ga—Zn—O layer are positioned close to those in an adjacent Ga—Zn—O layer. The oxygen atoms have negative charge, whereby the two Ga—Zn—O layers repel each other. As a result, the InGaZnO₄ crystal has a cleavage plane between the two adjacent Ga—Zn—O layers.

The substrate 5120 is placed to face the target 5130, and the distance d (also referred to as a target-substrate distance (T-S distance)) is greater than or equal to 0.01 m and less than or equal to 1 m, preferably greater than or equal to 0.02 m and less than or equal to 0.5 m. The deposition chamber is mostly filled with a deposition gas (e.g., an oxygen gas, an argon gas, or a mixed gas containing oxygen at 5 vol % or higher) and the pressure in the deposition chamber is controlled to be higher than or equal to 0.01 Pa and lower than or equal to 100 Pa, preferably higher than or equal to 0.1 Pa and lower than or equal to 10 Pa. Here, discharge starts by application of a voltage at a certain value or higher to the target 5130, and plasma is observed. The magnetic field forms a high-density plasma region in the vicinity of the target 5130. In the high-density plasma region, the deposition gas is ionized, so that an ion 5101 is generated. Examples of the ion 5101 include an oxygen cation (O⁺) and an argon cation (Ar⁺).

The ion 5101 is accelerated toward the target 5130 side by an electric field, and then collides with the target 5130. At this time, a pellet 5100a and a pellet 5100b which are flat-plate-like (pellet-like) sputtered particles are separated and sputtered from the cleavage plane. Note that structures of the pellet 5100a and the pellet 5100b may be distorted by an impact of collision of the ion 5101.

The pellet 5100a is a flat-plate-like (pellet-like) sputtered particle having a triangle plane, e.g., regular triangle plane. The pellet 5100b is a flat-plate-like (pellet-like) sputtered particle having a hexagon plane, e.g., regular hexagon plane. Note that flat-plate-like (pellet-like) sputtered particles such as the pellet 5100a and the pellet 5100b are collectively called pellets 5100. The shape of a flat plane of the pellet 5100 is not limited to a triangle or a hexagon. For example, the flat plane may have a shape formed by combining two or more triangles. For example, a quadrangle (e.g., rhombus) may be formed by combining two triangles (e.g., regular triangles).

The thickness of the pellet 5100 is determined depending on the kind of deposition gas and the like. The thicknesses of the pellets 5100 are preferably uniform; the reason for this is described later. In addition, the sputtered particle preferably has a pellet shape with a small thickness as compared to a dice shape with a large thickness. For example, the thickness of the pellet 5100 is greater than or equal to 0.4 nm and less than or equal to 1 nm, preferably greater than or equal to 0.6 nm and less than or equal to 0.8 nm. In addition, for example, the width of the pellet 5100 is greater than or equal to 1 nm and less than or equal to 3 nm, preferably greater than or equal to 1.2 nm and less than or equal to 2.5 nm. The pellet 5100 corresponds to the initial nucleus in the description of (1) in FIG. 29. For example, in the case where the ion 5101 collides with the target 5130 including an In—Ga—Zn oxide, the pellet 5100 that includes three layers of a Ga—Zn—O layer, an In—O layer, and a Ga—Zn—O layer as shown in FIG. 31B is ejected. Note that FIG. 31C shows the structure of the pellet 5100 observed from a direction parallel to the c-axis. Therefore, the pellet 5100 has a nanometer-sized sandwich structure including two Ga—Zn—O layers (pieces of bread) and an In—O layer (filling).

The pellet 5100 may receive a charge when passing through the plasma, so that side surfaces thereof are negatively or positively charged. The pellet 5100 includes an oxygen atom on its side surface, and the oxygen atom may be negatively charged. In this manner, when the side surfaces are charged with the same polarity, charges repel each other, and accordingly, the pellet 5100 can maintain a flat-plate shape. In the case where a CAAC-OS is an In—Ga—Zn oxide, there is a possibility that an oxygen atom bonded to an indium atom is negatively charged. There is another possibility that an oxygen atom bonded to an indium atom, a gallium atom, or a zinc atom is negatively charged. In addition, the pellet 5100 may grow by being bonded with an indium atom, a gallium atom, a zinc atom, an oxygen atom, or the like when passing through plasma. A difference in size between (2) and (1) in FIG. 29 corresponds to the amount of growth in plasma. Here, in the case where the temperature of the substrate 5120 is at around room temperature, the pellet 5100 does not grow anymore; thus, an nc-OS is formed (see FIG. 30B). An nc-OS can be deposited when the substrate 5120 has a large size because a temperature at which the deposition of an nc-OS is carried out is approximately room temperature. Note that in order that the pellet 5100 grows in plasma, it is effective to increase deposition power in sputtering. High deposition power can stabilize the structure of the pellet 5100.

As shown in FIGS. 30A and 30B, the pellet 5100 flies like a kite in plasma and flutters up to the substrate 5120. Since the pellets 5100 are charged, when the pellet 5100 gets close to a region where another pellet 5100 has already been deposited, repulsion is generated. Here, above the substrate 5120, a magnetic field in a direction parallel to the top surface of the substrate 5120 (also referred to as a horizontal magnetic field) is generated. A potential difference is given between the substrate 5120 and the target 5130, and accordingly, current flows from the substrate 5120 toward the target 5130. Thus, the pellet 5100 is given a force (Lorentz force) on the top surface of the substrate 5120 by an effect of the magnetic field and the current. This is explainable with Fleming's left-hand rule.

The mass of the pellet 5100 is larger than that of an atom. Therefore, to move the pellet 5100 over the top surface of the substrate 5120, it is important to apply some force to the pellet 5100 from the outside. One kind of the force may be force which is generated by the action of a magnetic field and current. In order to increase a force applied to the pellet 5100, it is preferable to provide, on the top surface, a region where the magnetic field in a direction parallel to the top surface of the substrate 5120 is 10 G or higher, preferably 20 G or higher, further preferably 30 G or higher, still further preferably 50 G or higher. Alternatively, it is preferable to provide, on the top surface, a region where the magnetic field in a direction parallel to the top surface of the substrate 5120 is 1.5 times or higher, preferably twice or higher, further preferably 3 times or higher, still further preferably 5 times or higher as high as the magnetic field in a direction perpendicular to the top surface of the substrate 5120.

At this time, the magnets and the substrate 5120 are moved or rotated relatively, whereby the direction of the horizontal magnetic field on the top surface of the substrate 5120 continues to change. Therefore, the pellet 5100 can be moved in various directions on the top surface of the substrate 5120 by receiving forces in various directions.

Furthermore, as shown in FIG. 30A, when the substrate 5120 is heated, resistance between the pellet 5100 and the substrate 5120 due to friction or the like is low. As a result, the pellet 5100 glides above the top surface of the substrate 5120. The glide of the pellet 5100 is caused in a state where its flat plane faces the substrate 5120. Then, when the pellet 5100 reaches the side surface of another pellet 5100 that has been already deposited, the side surfaces of the pellets 5100 are bonded. At this time, the oxygen atom on the side surface of the pellet 5100 is released. With the released oxygen atom, oxygen vacancies in a CAAC-OS might be filled; thus, the CAAC-OS has a low density of defect states. Note that the temperature of the top surface of the substrate 5120 is, for example, higher than or equal to 100° C. and lower than 500° C., higher than or equal to 150° C. and lower than 450° C., or higher than or equal to 170° C. and lower than 400° C. Hence, even when the substrate 5120 has a large size, it is possible to deposit a CAAC-OS.

Furthermore, the pellet 5100 is heated on the substrate 5120, whereby atoms are rearranged, and the structure distortion caused by the collision of the ion 5101 can be reduced. The pellet 5100 whose structure distortion is reduced is substantially single crystal. Even when the pellets 5100 are heated after being bonded, expansion and contraction of the pellet 5100 itself hardly occur, which is caused by turning the pellet 5100 into substantially single crystal. Thus, formation of defects such as a grain boundary due to expansion of a space between the pellets 5100 can be prevented, and accordingly, generation of crevasses can be prevented.

The CAAC-OS does not have a structure like a board of a single crystal oxide semiconductor but has arrangement with a group of pellets 5100 (nanocrystals) like stacked bricks or blocks. Furthermore, a grain boundary does not exist therebetween. Therefore, even when deformation such as shrink occurs in the CAAC-OS owing to heating during deposition, heating or bending after deposition, it is possible to relieve local stress or release distortion. Therefore, this structure is suitable for a flexible semiconductor device. Note that the nc-OS has arrangement in which pellets 5100 (nanocrystals) are randomly stacked.

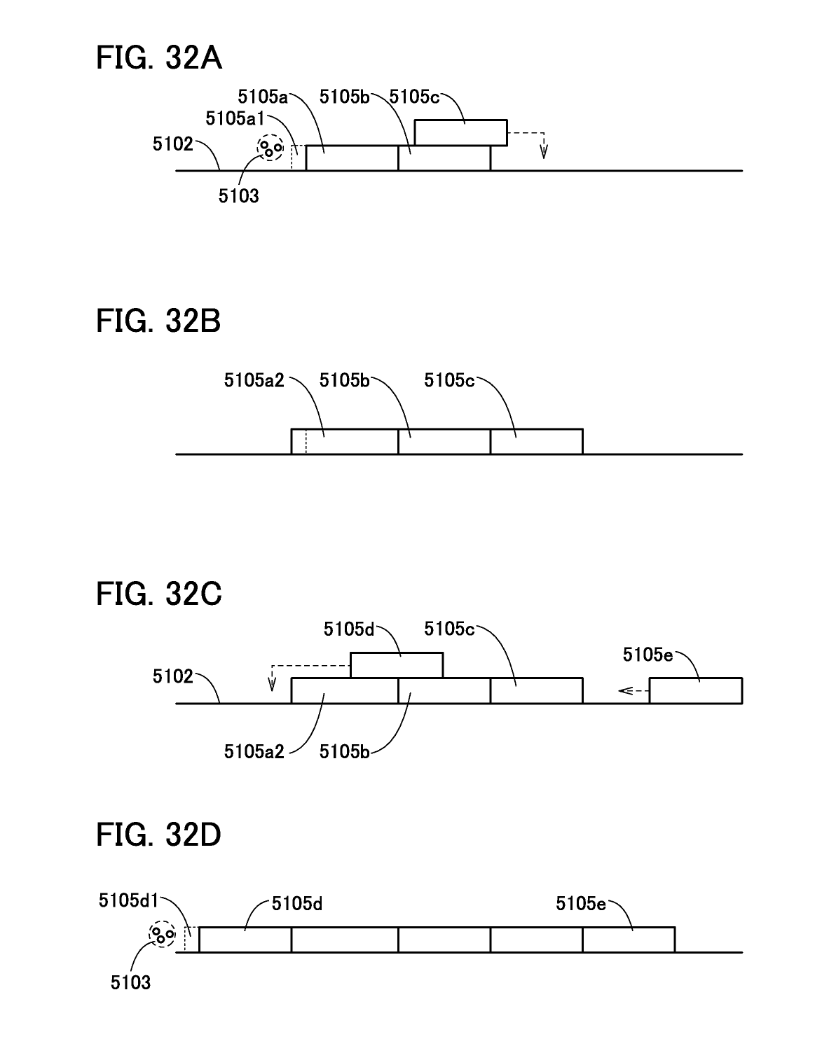

When the target is sputtered with an ion, in addition to the pellets, zinc oxide or the like may be ejected. The zinc oxide is lighter than the pellet and thus reaches the top surface of the substrate 5120 before the pellet. As a result, the zinc oxide forms a zinc oxide layer 5102 with a thickness greater than or equal to 0.1 nm and less than or equal to 10 nm, greater than or equal to 0.2 nm and less than or equal to 5 nm, or greater than or equal to 0.5 nm and less than or equal to 2 nm. FIGS. 32A to 32D are cross-sectional schematic views.

As illustrated in FIG. 32A, a pellet 5105a and a pellet 5105b are deposited over the zinc oxide layer 5102. Here, side surfaces of the pellet 5105a and the pellet 5105b are in contact with each other. In addition, a pellet 5105c is deposited over the pellet 5105b, and then glides over the pellet 5105b. Furthermore, a plurality of particles 5103 ejected from the target together with the zinc oxide is crystallized by heating of the substrate 5120 to form a region 5105a1 on another side surface of the pellet 5105a. Note that the plurality of particles 5103 may contain oxygen, zinc, indium, gallium, or the like.

Then, as illustrated in FIG. 32B, the region 5105a1 grows to part of the pellet 5105a to form a pellet 5105a2. In addition, a side surface of the pellet 5105c is in contact with another side surface of the pellet 5105b.

Next, as illustrated in FIG. 32C, a pellet 5105d is deposited over the pellet 5105a2 and the pellet 5105b, and then glides over the pellet 5105a2 and the pellet 5105b. Furthermore, a pellet 5105e glides toward another side surface of the pellet 5105c over the zinc oxide layer 5102.

Then, as illustrated in FIG. 32D, the pellet 5105d is placed so that a side surface of the pellet 5105d is in contact with a side surface of the pellet 5105a2. Furthermore, a side surface of the pellet 5105e is in contact with another side surface of the pellet 5105c. A plurality of particles 5103 ejected from the target together with the zinc oxide is crystallized by heating of the substrate 5120 to form a region 5105d1 on another side surface of the pellet 5105d.

As described above, deposited pellets are placed to be in contact with each other and then growth is caused at side surfaces of the pellets, whereby a CAAC-OS is formed over the substrate 5120. Therefore, each pellet of the CAAC-OS is larger than that of the nc-OS. A difference in size between (3) and (2) in FIG. 29 corresponds to the amount of growth after deposition.

When spaces between pellets 5100 are extremely small, the pellets may form a large pellet. The large pellet has a single crystal structure. For example, the size of the large pellet may be greater than or equal to 10 nm and less than or equal to 200 nm, greater than or equal to 15 nm and less than or equal to 100 nm, or greater than or equal to 20 nm and less than or equal to 50 nm, when seen from the above. Therefore, when a channel formation region of a transistor is smaller than the large pellet, the region having a single crystal structure can be used as the channel formation region. Furthermore, when the size of the pellet is increased, the region having a single crystal structure can be used as the channel formation region, the source region, and the drain region of the transistor.

In this manner, when the channel formation region or the like of the transistor is formed in a region having a single crystal structure, the frequency characteristics of the transistor can be increased in some cases.

As shown in such a model, the pellets 5100 are considered to be deposited on the substrate 5120. Thus, a CAAC-OS can be deposited even when a formation surface does not have a crystal structure, which is different from film deposition by epitaxial growth. For example, even when the top surface (formation surface) of the substrate 5120 has an amorphous structure (e.g., the top surface is formed of amorphous silicon oxide), a CAAC-OS can be formed.

In addition, it is found that in formation of the CAAC-OS, the pellets 5100 are arranged in accordance with the top surface shape of the substrate 5120 that is the formation surface even when the formation surface has unevenness. For example, in the case where the top surface of the substrate 5120 is flat at the atomic level, the pellets 5100 are arranged so that flat planes parallel to the a-b plane face downwards. In the case where the thicknesses of the pellets 5100 are uniform, a layer with a uniform thickness, flatness, and high crystallinity is formed. By stacking n layers (n is a natural number), the CAAC-OS can be obtained.

In the case where the top surface of the substrate 5120 has unevenness, a CAAC-OS in which n layers (n is a natural number) in each of which the pellets 5100 are arranged along the unevenness are stacked is formed. Since the substrate 5120 has unevenness, a gap is easily generated between the pellets 5100 in the CAAC-OS in some cases. Note that owing to intermolecular force, the pellets 5100 are arranged so that a gap between the pellets is as small as possible even on the unevenness surface. Therefore, even when the formation surface has unevenness, a CAAC-OS with high crystallinity can be obtained.

As a result, laser crystallization is not needed for formation of a CAAC-OS, and a uniform film can be formed even over a large-sized glass substrate or the like.

Since a CAAC-OS is deposited in accordance with such a model, the sputtered particle preferably has a pellet shape with a small thickness. Note that when the sputtered particles have a dice shape with a large thickness, planes facing the substrate 5120 vary; thus, the thicknesses and orientations of the crystals cannot be uniform in some cases.

According to the deposition model described above, a CAAC-OS with high crystallinity can be formed even on a formation surface with an amorphous structure.

[Formation of Source Electrode 209a, Drain Electrode 209b, and the Like]

Next, the source electrode 209a, the drain electrode 209b, the wiring 219, and the terminal electrode 216 are formed (see FIG. 14C). First, a conductive film is formed over the gate insulating layer 207 and the semiconductor layer 208.

The conductive film can be formed to have a single-layer structure or a stacked-layer structure using any of metals such as aluminum, titanium, chromium, nickel, copper, yttrium, zirconium, molybdenum, silver, tantalum, and tungsten or an alloy containing any of these metals as its main component. For example, a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which a titanium film or a titanium nitride film, an aluminum film or a copper film, and a titanium film or a titanium nitride film are stacked in this order, a three-layer structure in which a molybdenum film or a molybdenum nitride film, an aluminum film or a copper film, and a molybdenum film or a molybdenum nitride film are stacked in this order, and a three-layer structure in which a tungsten film, a copper film, and a tungsten film are stacked in this order can be given.

Note that a conductive material containing oxygen such as indium tin oxide, zinc oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added, or a conductive material containing nitrogen such as titanium nitride or tantalum nitride may be used. It is also possible to use a stacked-layer structure formed using a material containing the above metal element and conductive material containing oxygen. It is also possible to use a stacked-layer structure formed using a material containing the above metal element and conductive material containing nitrogen. It is also possible to use a stacked-layer structure formed using a material containing the above metal element, conductive material containing oxygen, and conductive material containing nitrogen.

The thickness of the conductive film is greater than or equal to 5 nm and less than or equal to 500 nm, preferably greater than or equal to 10 nm and less than or equal to 300 nm, further preferably greater than or equal to 10 nm and less than or equal to 200 nm. In this embodiment, a 300-nm-thick indium tin oxide film is formed as the conductive film.

Then, part of the conductive film is selectively etched using a resist mask to form the source electrode 209a, the drain electrode 209b, the wiring 219, and the terminal electrode 216 (including other electrodes and wirings formed in the same layer). The resist mask can be formed by a photolithography method, a printing method, an inkjet method, or the like as appropriate. Formation of the resist mask by an inkjet method needs no photomask; thus, manufacturing cost can be reduced.

The conductive film may be etched by a dry etching method, a wet etching method, or both a dry etching method and a wet etching method. Note that an exposed portion of the semiconductor layer 208 is removed by the etching step in some cases. The resist mask is removed after the etching.

With the source electrode 209a and the drain electrode 209b, the transistor 242 and the transistor 252 are completed.

### [Formation of Insulating Layer]

Next, the insulating layer 210 is formed over the source electrode 209a, the drain electrode 209b, the wiring 219, and the terminal electrode 216 (see FIG. 14D). The insulating layer 210 can be formed using a material and a method similar to those of the insulating layer 205.

In the case where an oxide semiconductor is used for the semiconductor layer 208, an insulating layer containing oxygen is preferably used for at least part of the insulating layer 210 that is in contact with the semiconductor layer 208. For example, in the case where the insulating layer 210 is a stack of a plurality of layers, at least a layer that is in contact with the semiconductor layer 208 is preferably formed using silicon oxide.

### [Formation of Opening 128]

Next, part of the insulating layer 210 is selectively etched using a resist mask to form the opening 128 (see FIG. 14D). At the same time, another opening that is not illustrated can also be formed. The resist mask can be formed by a photolithography method, a printing method, an ink jet method, or the like as appropriate. Formation of the resist mask by an ink jet method needs no photomask; thus, manufacturing cost can be reduced.

The insulating layer 210 may be etched by a dry etching method, a wet etching method, or both a dry etching method and a wet etching method.

The drain electrode 209b and the terminal electrode 216 are partly exposed by the formation of the opening 128. The resist mask is removed after the formation of the opening 128.

### [Formation of Insulating Layer 211]

Next, the insulating layer 211 is formed over the insulating layer 210 (see FIG. 14E). The insulating layer 211 can be formed using a material and a method similar to those of the insulating layer 205.

Planarization treatment may be performed on the insulating layer 211 to reduce unevenness of a surface on which the light-emitting element 125 is formed. The planarization treatment may be, but not particularly limited to, polishing treatment (e.g., chemical mechanical polishing (CMP)) or dry etching treatment.

Forming the insulating layer 211 using an insulating material with a planarization function can omit polishing treatment. As the insulating material with a planarization function, for example, an organic material such as a polyimide resin or an acrylic resin can be used. Other than such organic materials, it is also possible to use a low-dielectric constant material (a low-k material) or the like. Note that the insulating layer 211 may be formed by stacking a plurality of insulating layers formed of any of these materials.

Part of the insulating layer 211 that overlaps with the opening 128 is removed to form an opening 129 (see FIG. 14E). At the same time, another opening that is not illustrated can also be formed. In addition, the insulating layer 211 in a region to which the external electrode 124 is connected later is removed. Note that the opening 129 or the like can be formed in such a manner that a resist mask is formed by a photolithography process over the insulating layer 211 and a region of the insulating layer 211 that is not covered with the resist mask is etched. A surface of the drain electrode 209b is exposed by the formation of the opening 129.

When the insulating layer 211 is formed using a photosensitive material, the opening 129 can be formed without the resist mask. In this embodiment, a photosensitive acrylic resin is used to form the insulating layer 211 and the opening 129.

### [Formation of Electrode 115]

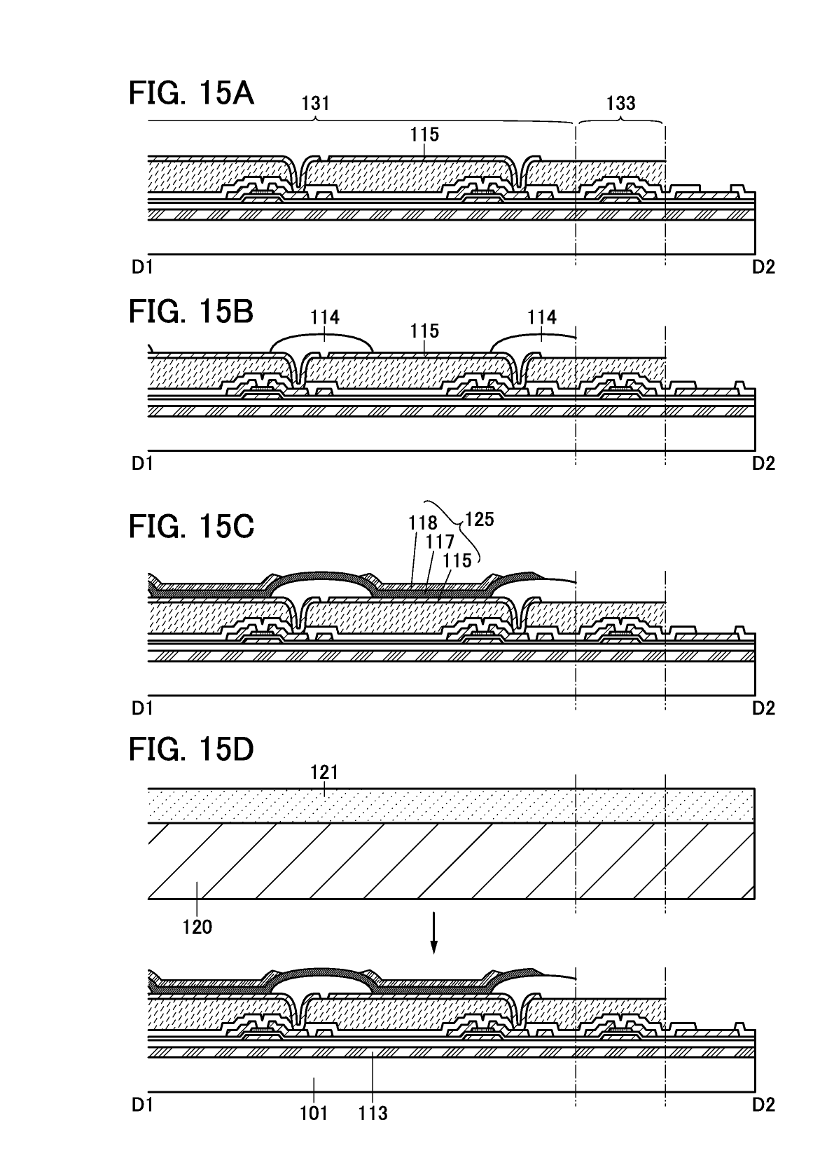

Next, the electrode 115 is formed over the insulating layer 211 (see FIG. 15A). The electrode 115 is preferably formed using a conductive material that transmits light emitted from the EL layer 117 formed later. Note that the electrode 115 may have a stacked-layer structure of a plurality of layers without limitation to a single-layer structure. For example, in the case where the electrode 115 is used as an anode, a layer that is in contact with the EL layer 117 may be a light-transmitting layer, such as an indium tin oxide layer, having a higher work function than the EL layer 117.

Note that although the display device having a bottom-emission structure is described as an example in this embodiment, a display device having a top-emission structure or a dual-emission structure may be used.

The electrode 115 can be formed in such a manner that a conductive film to be the electrode 115 is formed over the insulating layer 211, a resist mask is formed over the conductive film, and a region of the conductive film that is not covered with the resist mask is etched. The conductive film can be etched by a dry etching method, a wet etching method, or both a dry etching method and a wet etching method. The resist mask can be formed by a photolithography method, a printing method, an inkjet method, or the like as appropriate. Formation of the resist mask by an ink jet method needs no photomask; thus, manufacturing cost can be reduced. The resist mask is removed after the formation of the electrode 115.

### [Formation of Partition 114]

Next, the partition 114 is formed (see FIG. 15B). The partition 114 is provided to prevent an unintentional electric short-circuit between light-emitting elements 125 of adjacent light-emitting portions 132 and unintended light emission therefrom. In the case of using a metal mask for formation of the EL layer 117 described later, the partition 114 has a function of preventing the contact of the metal mask with the electrode 115. The partition 114 can be formed of an organic resin material such as an epoxy resin, an acrylic resin, or an imide resin, or an inorganic material such as silicon oxide. The partition 114 is preferably formed so that its sidewall has a tapered shape or a tilted surface with a continuous curvature. The sidewall of the partition 114 having the above-described shape enables favorable coverage with the EL layer 117 and the electrode 118 formed later.

### [Formation of EL Layer 117]

Next, the EL layer 117 is formed over the electrode 115 (see FIG. 15C). A structure of the EL layer 117 is described in Embodiment 5.

### [Formation of Electrode 118]

Next, the electrode 118 is formed over the EL layer 117 (see FIG. 15C). The electrode 118 can be formed using a material and a method similar to those in Embodiment 1. The light-emitting element 125 includes the electrode 115, the EL layer 117, and the electrode 118.

### [Attachment of Substrate 121]

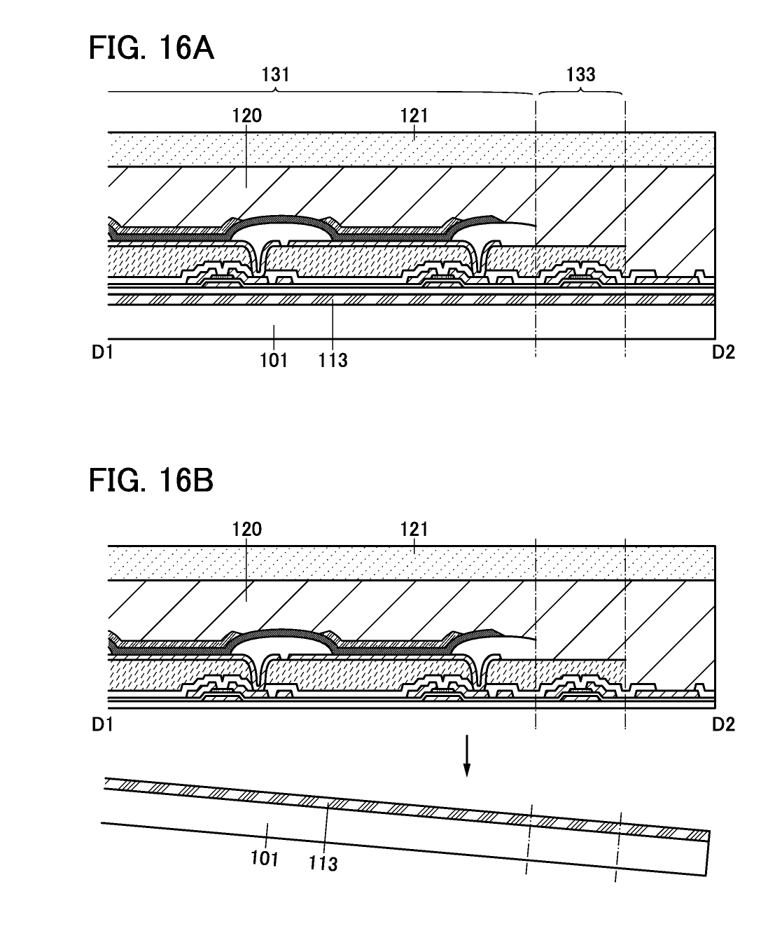

Next, the substrate 121 is formed over the substrate 111 with the bonding layer 120 provided therebetween (see FIG. 15D and FIG. 16A). A light curable adhesive, a reactive curable adhesive, a thermosetting adhesive, or an anaerobic adhesive can be used as the bonding layer 120. For example, an epoxy resin, an acrylic resin, or an imide resin can be used. The bonding layer 120 may be mixed with a drying agent (such as zeolite). Note that the substrate 121 is formed to face the element formation substrate 101 and may thus be referred to as a counter substrate.

[Separation of Element Formation Substrate from Insulating Layer 205]

Next, the element formation substrate 101 attached to the insulating layer 205 with the separation layer 113 provided therebetween is separated from the insulating layer 205 (see FIG. 16B). As a separation method, mechanical force (a separation process with a human hand or a gripper, a separation process by rotation of a roller, ultrasonic waves, or the like) may be used. For example, a cut is made in the separation layer 113 with a sharp edged tool, by laser light irradiation, or the like and water is injected into the cut. Alternatively, the cut is sprayed with a mist of water. A portion between the separation layer 113 and the insulating layer 205 absorbs water through capillarity action, so that the element formation substrate 101 can be separated easily from the insulating layer 205.

### [Attachment of Substrate]

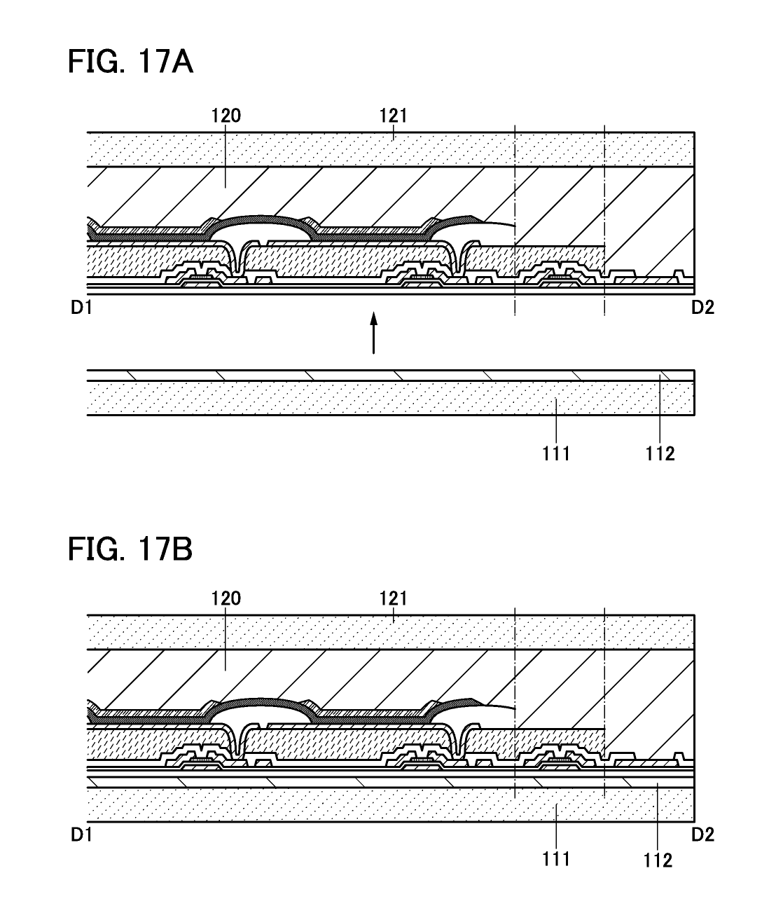

Next, the substrate 111 is attached to the insulating layer 205 with the bonding layer 112 provided therebetween (see FIGS. 17A and 17B). The bonding layer 112 can be formed using a material similar to that of the bonding layer 120. In this embodiment, a 20-μm-thick aramid (polyamide resin) is used for the substrate 111.

### [Formation of Opening 122]

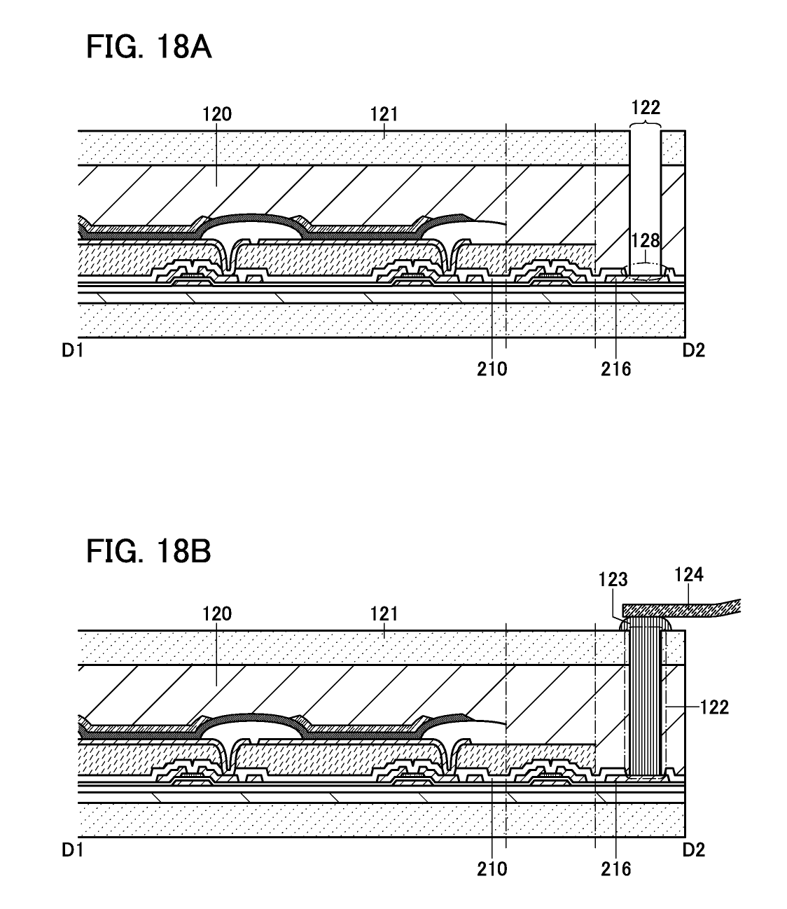

Next, the substrate 121 and the bonding layer 120 in a region overlapping with the terminal electrode 216 and the opening 128 are removed to form an opening 122 (see FIG. 18A). A surface of the terminal electrode 216 is partly exposed by the formation of the opening 122.

### [Formation of External Electrode]

Next, the anisotropic conductive connection layer 123 is formed in the opening 122, and the external electrode 124 for inputting electric power or a signal to the light-emitting device 250 is formed over the anisotropic conductive connection layer 123 (see FIG. 18B). The terminal electrode 216 is electrically connected to the external electrode 124 through the anisotropic conductive connection layer 123. For example, a flexible printed circuit (FPC) can be used as the external electrode 124.

The anisotropic conductive connection layer 123 can be formed using any of various kinds of anisotropic conductive films (ACF), anisotropic conductive pastes (ACP), and the like.

The anisotropic conductive connection layer 123 is formed by curing a paste-form or sheet-form material that is obtained by mixing conductive particles to a thermosetting resin or a thermosetting, light curable resin. The anisotropic conductive connection layer 123 exhibits an anisotropic conductive property by light irradiation or thermocompression bonding. As the conductive particles used for the anisotropic conductive connection layer 123, for example, particles of a spherical organic resin coated with a thin-film metal such as Au, Ni, or Co can be used.

In the above-described manner, the light-emitting device 250 can be manufactured.

### <Modification Example 1 of Light-Emitting Device>

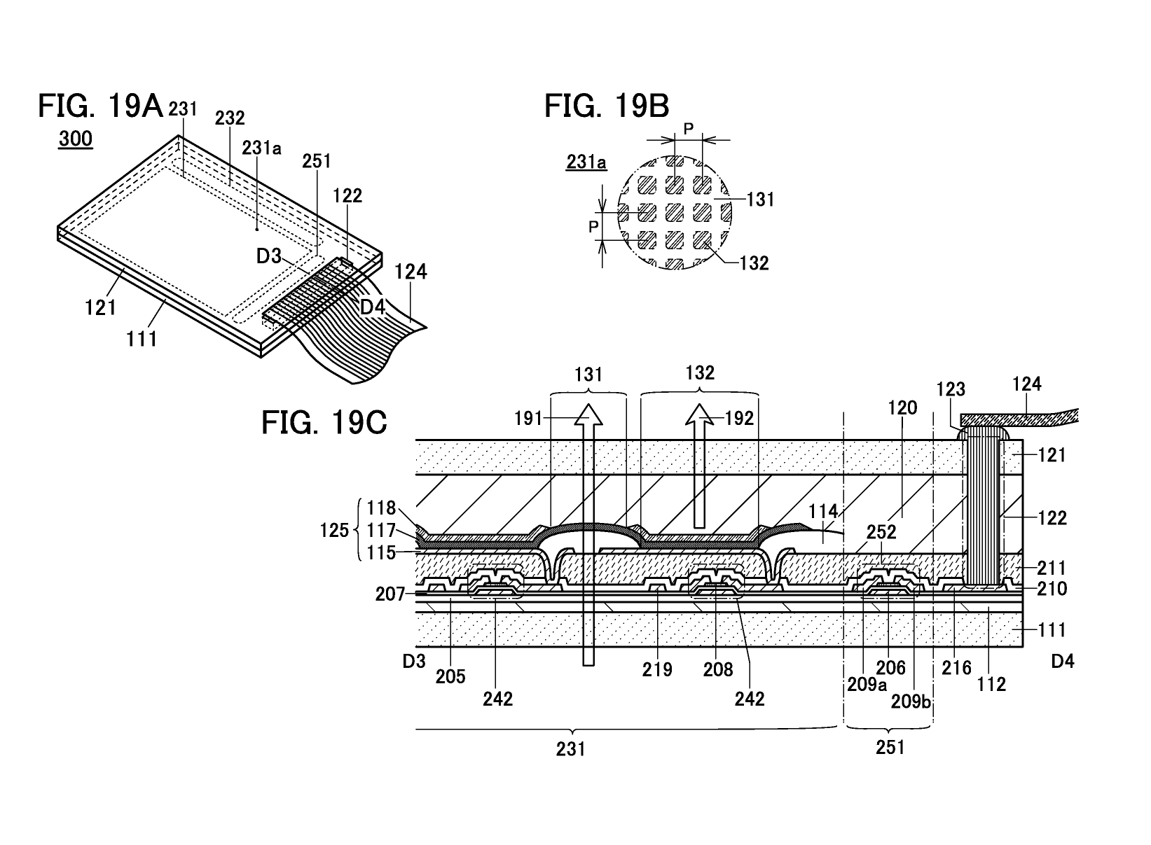

An example in which the light-emitting device 250 having a bottom-emission structure described in this embodiment is modified into a light-emitting device 250 having a top-emission structure is described with reference to FIGS. 19A to 19C. FIG. 19A is a perspective view of the light-emitting device 250 having a top-emission structure. FIG. 19B is an enlarged view of part of the display region 231 which is illustrated as a portion 231a in FIG. 19A. In addition, FIG. 19C is a cross-sectional view of a portion denoted by a dashed-dotted line D3-D4 in FIG. 19A.

In the case where the light-emitting device 250 having a bottom-emission structure is modified into the light-emitting device 250 having a top-emission structure, the electrode 115 is formed using a material having a function of reflecting light and the electrode 118 is formed using a material having a function of transmitting light.

Note that the electrode 115 and the electrode 118 may have a stacked-layer structure of a plurality of layers without limitation to a single-layer structure. For example, in the case where the electrode 115 is used as an anode, a layer in contact with the EL layer 117 may be a light-transmitting layer, such as an indium tin oxide layer, having a work function higher than that of the EL layer 117 and a layer having high reflectance (e.g., aluminum, an alloy containing aluminum, or silver) may be provided in contact with the layer.

Light 191 that is incident on the light-emitting device 250 having a top-emission structure from the substrate 111 side is transmitted to the substrate 121 side through the light-transmitting portion 131. In other words, the state of the substrate 111 side can be observed on the substrate 121 side through the light-transmitting portion 131.

Light 192 is emitted from the light-emitting element 125 to the substrate 121 side. That is, even when a transistor or the like is formed so as to overlap with the light-emitting portion 132, emission of the light 192 is not hindered. Thus, the light 192 can be emitted efficiently, whereby power consumption can be reduced. In addition, the circuit design can be performed easily; thus, the productivity of the light-emitting device can be increased. Moreover, a wiring or the like overlapping with the light-transmitting portion 131 is provided so as to overlap with the light-emitting portion 132, whereby transmittance of the light-transmitting portion 131 can be improved. Thus, the state of the substrate 111 side can be viewed more clearly.

### <Modification Example 2 of Light-Emitting Device>

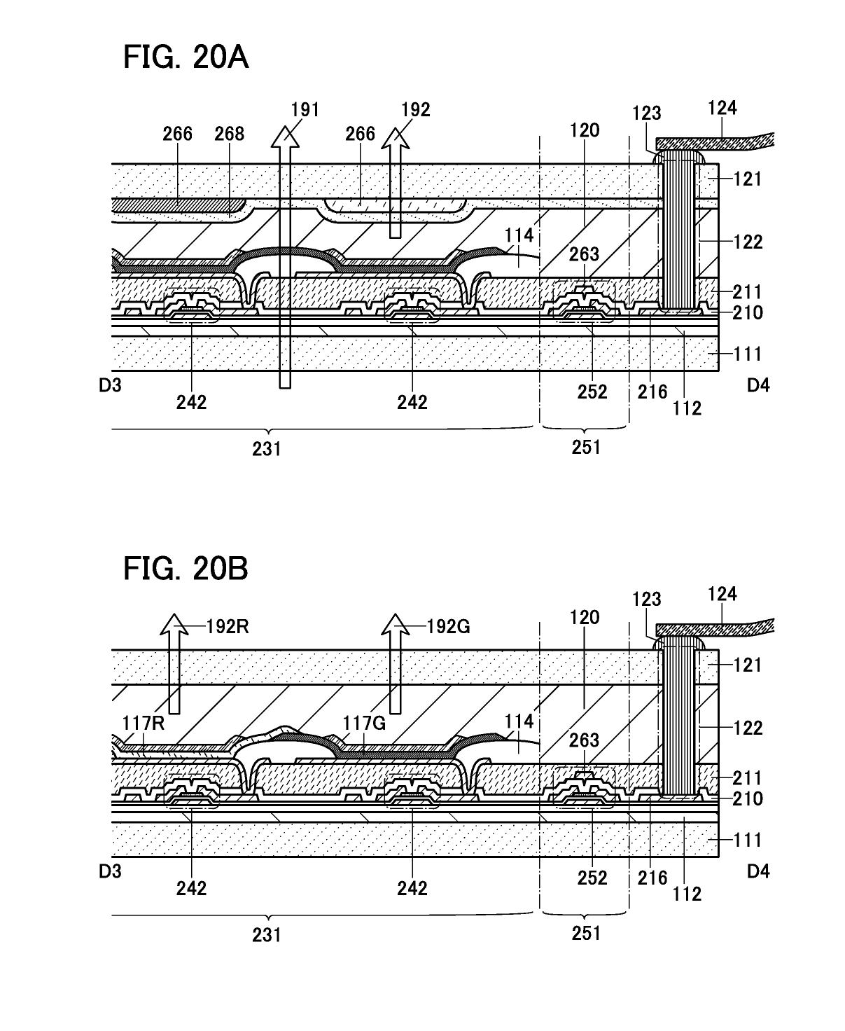

A structural example in which the light-emitting device 250 having a top-emission structure is modified into a light-emitting device 250 having a top-emission structure which is capable of color display by addition of a coloring layer is described with reference to FIG. 20A. In addition, FIG. 20A is a cross-sectional view of a portion denoted by the dashed-dotted line D3-D4 in FIG. 19A.

The light-emitting device 250 having a top-emission structure illustrated in FIG. 20A includes a coloring layer 266 and an overcoat layer 268 covering the coloring layer 266 over the substrate 121. The coloring layer 266 overlaps with the light-emitting portion 132. Light 192 is colored a given color by transmitting the coloring layer 266. For example, a light-emitting device capable of full color display can be achieved in such a manner that, in adjacent three light-emitting portions 132, overlapping coloring layers 266 serve as a red coloring layer 266, a green coloring layer 266, and a blue coloring layer 266. The coloring layers 266 are each formed with any of various materials by a printing method, an ink jet method, a photolithography method, or the like.

For the overcoat layer 268, an organic insulating layer of an acrylic resin, an epoxy resin, polyimide, or the like can be used. With the overcoat layer 268, an impurity or the like contained in the coloring layer 266 can be prevented from diffusing into the light-emitting element 125 side, for example. Note that the overcoat layer 268 is not necessarily formed.

A light-transmitting conductive film may be formed as the overcoat layer 268. The light-transmitting conductive film is formed as the overcoat layer 268, so that the light 235 emitted from the light-emitting element 125 can be transmitted through the overcoat layer 268 and the like and ionized impurities can be prevented from passing through the overcoat layer 268.

The light-transmitting conductive film can be formed using, for example, indium oxide, indium tin oxide, indium zinc oxide, zinc oxide, or zinc oxide to which gallium is added. Graphene or a metal film that is thin enough to have a light-transmitting property can also be used.

Note that FIG. 20A illustrates an example in which an electrode 263 is provided through the insulating layer 210 in a region overlapping with the semiconductor layer 208 of the transistor 252 included in the driver circuit 233. The electrode 263 can be formed using a material and a method similar to those of the gate electrode 206.

The electrode 263 can also serve as a gate electrode. In the case where one of the gate electrode 206 and the electrode 263 is simply referred to as a “gate electrode”, the other may be referred to as a “back gate electrode”. One of the gate electrode 206 and the electrode 226 is referred to as a “first gate electrode”, and the other is referred to as a “second gate electrode” in some cases.

In general, the back gate electrode is formed using a conductive film and located so that the channel formation region of the semiconductor layer is between the gate electrode and the back gate electrode. Thus, the back gate electrode can function in a manner similar to that of the gate electrode. The potential of the back gate electrode may be the same as that of the gate electrode or may be a GND potential or a predetermined potential. By changing a potential of the back gate electrode, the threshold voltage of the transistor can be changed.

Furthermore, the gate electrode and the back gate electrode are formed using conductive films and thus each have a function of preventing an electric field generated outside the transistor from influencing the semiconductor layer in which the channel is formed (in particular, a function of blocking static electricity).

By providing the gate electrode 206 and the electrode 263 with the semiconductor layer 208 provided therebetween and setting the potentials of the gate electrode 206 and the electrode 263 to be equal, carriers are induced to the semiconductor layer 208 from both the upper surface side and the lower surface side and a region of the semiconductor layer 208 through which carriers flow is enlarged in the film thickness direction; thus, the number of transferred carriers is increased. As a result, the on-state current and the field-effect mobility of the transistor are increased.

The gate electrode 206 and the electrode 263 each have a function of blocking an external electric field; thus, charges in a layer under the gate electrode 206 and in a layer over the electrode 263 do not influence the semiconductor layer 208. Thus, there is little change in the threshold voltage in a stress test (e.g., a negative gate bias temperature (−GBT) stress test in which a negative voltage is applied to a gate or a +GBT stress test in which a positive voltage is applied to a gate). In addition, changes in the rising voltages of on-state current at different drain voltages can be suppressed.

The BT stress test is one kind of accelerated test and can evaluate, in a short time, change in characteristics (i.e., a change over time) of transistors, which is caused by long-term use. In particular, the amount of change in threshold voltage of the transistor between before and after the BT stress test is an important indicator when examining the reliability of the transistor. If the amount of change in the threshold voltage between before and after the BT stress test is small, the transistor has higher reliability.

By providing the gate electrode 206 and the electrode 263 and setting the potentials of the gate electrode 206 and the electrode 263 to be the same, the amount of change in the threshold voltage is reduced. Accordingly, variation in electrical characteristics among a plurality of transistors is also reduced.

Note that a back gate electrode may be provided in the transistor 242 formed in the display region 231.

### <Modification Example 3 of Light-Emitting Device>

Another structural example in which the light-emitting device 250 having a top-emission structure is modified into a light-emitting device 250 having a top-emission structure which is capable of color display without the coloring layer 266 is described with reference to FIG. 20B.

In the light-emitting device 250 having a top-emission structure illustrated in FIG. 20B, color display can be performed by using an EL layer 117R, an EL layer 117G, an EL layer 117B (not illustrated), and the like instead of the coloring layer 266 and the overcoat layer 268. The EL layer 117R, the EL layer 117G, the EL layer 117B, and the like can emit light of the different colors such as red, green, and blue. For example, the EL layer 117R emits light 192R of a red wavelength, the EL layer 117G emits light 192G of a green wavelength, and the EL layer 117B emits light 192B (not illustrated) of a blue wavelength.

Since the coloring layer 266 is not provided, a reduction in luminance caused when the light 192R, the light 192G, and the light 192B are transmitted through the coloring layer 266 can be prevented. The thicknesses of the EL layer 117R, the EL layer 117G, and the EL layer 117B are adjusted in accordance with the wavelengths of the light 192R, the light 192G, and the light 192B, whereby a higher color purity can be achieved.

### <Modification Example 4 of Light-Emitting Device>

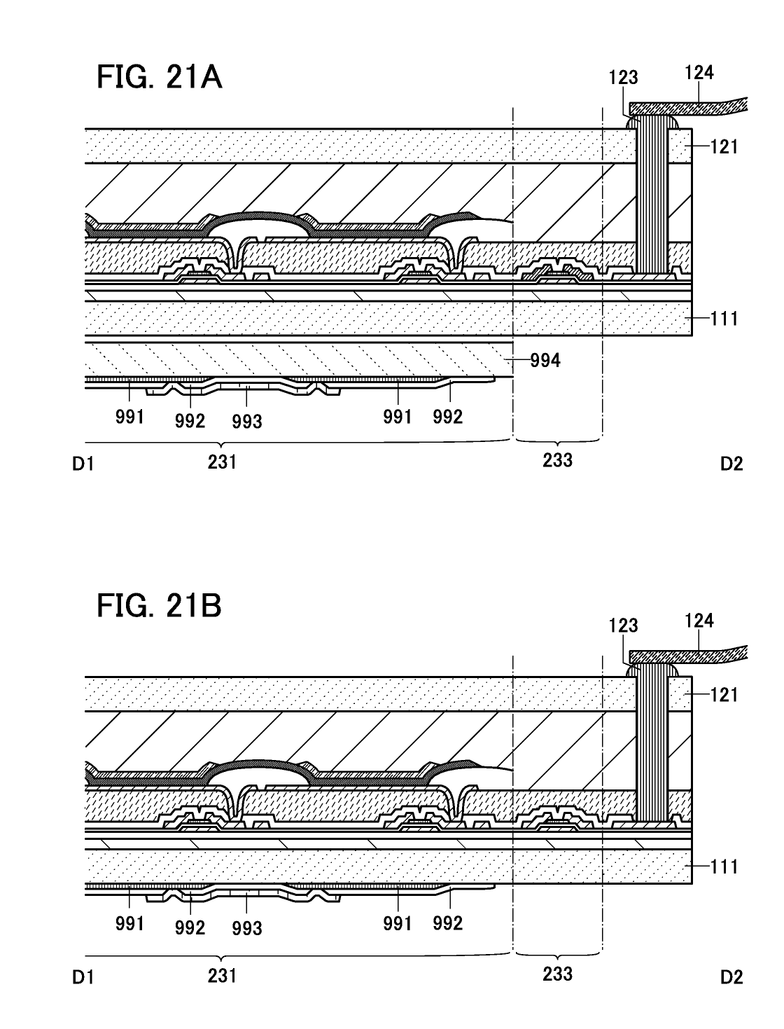

In the light-emitting device 250, a substrate provided with a touch sensor may be provided on the substrate 111 side as illustrated in FIG. 21A. The touch sensor is formed using the conductive layer 991, the conductive layer 993, and the like. In addition, the insulating layer 992 is formed between the conductive layers.

As the conductive layer 991 and/or the conductive layer 993, a transparent conductive film of indium tin oxide, indium zinc oxide, or the like is preferably used. Note that a layer containing a low-resistance material may be used for part or the whole of the conductive layer 991 and/or the conductive layer 993 in order to reduce resistance. For example, the conductive layer 991 and/or the conductive layer 993 can be formed as a single layer or a stack using any of metals such as aluminum, titanium, chromium, nickel, copper, yttrium, zirconium, molybdenum, silver, tantalum, and tungsten and an alloy containing any of these metals as a main component. Alternatively, a metal nanowire may be used as the conductive layer 991 and/or the conductive layer 993. Silver or the like is preferably used as a metal for the metal nanowire, in which case the resistance value can be reduced and the sensitivity of the sensor can be improved.

The insulating layer 992 is preferably formed as a single layer or a multilayer using silicon oxide, silicon nitride, silicon oxynitride, silicon nitride oxide, aluminum oxide, aluminum oxynitride, aluminum nitride oxide, or the like. The insulating layer 992 can be formed by a sputtering method, a CVD method, a thermal oxidation method, a coating method, a printing method, or the like.

Although an example in which the touch sensor is provided on the substrate 111 side is illustrated in FIG. 21A, one embodiment of the present invention is not limited thereto. The touch sensor may be provided on the substrate 121 side.

Note that the substrate 994 may have a function as an optical film. That is, the substrate 994 may have a function of a polarizing plate, a retardation plate, or the like.

Moreover, a touch sensor may be directly formed on the substrate 111 as illustrated in FIG. 21B.

This embodiment can be implemented in an appropriate combination with any of the structures described in the other embodiments.

### Embodiment 5

In this embodiment, a structural example of a light-emitting element that can be used as the light-emitting element 125 will be described. Note that an EL layer 320 described in this embodiment corresponds to the EL layer 117 described in the above embodiments.

### <Structure of Light-Emitting Element>

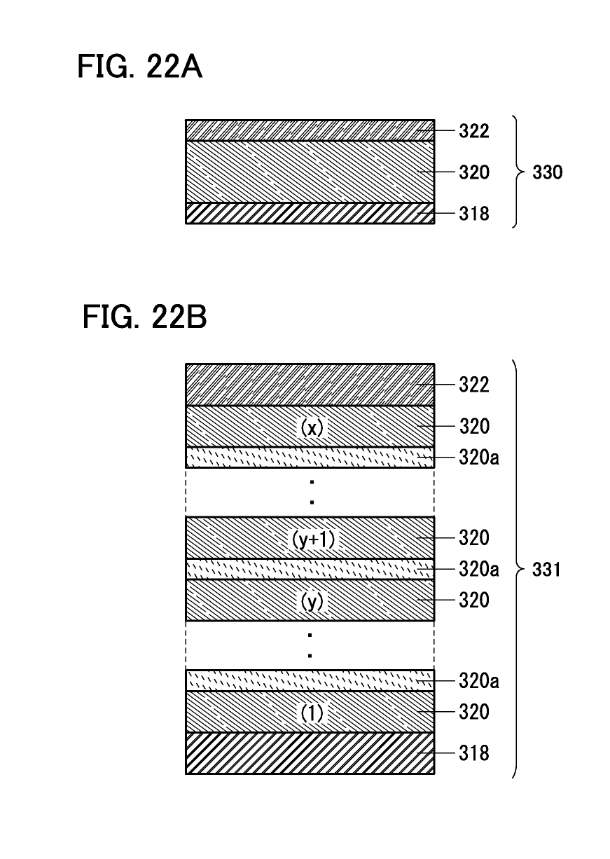

In a light-emitting element 330 illustrated in FIG. 22A, the EL layer 320 is interposed between a pair of electrodes (an electrode 318 and an electrode 322). Note that the electrode 318 is used as an anode and the electrode 322 is used as a cathode as an example in the following description of this embodiment.

The EL layer 320 includes at least a light-emitting layer and may have a stacked-layer structure including a functional layer other than the light-emitting layer. As the functional layer other than the light-emitting layer, a layer containing a substance having a high hole-injection property, a substance having a high hole-transport property, a substance having a high electron-transport property, a substance having a high electron-injection property, a bipolar substance (a substance having high electron- and hole-transport properties), or the like can be used. Specifically, functional layers such as a hole-injection layer, a hole-transport layer, an electron-transport layer, an electron-injection layer, and the like can be used in appropriate combination.

The light-emitting element 330 illustrated in FIG. 22A emits light when current flows because of a potential difference generated between the electrode 318 and the electrode 322 and holes and electrons are recombined in the EL layer 320. That is, a light-emitting region is formed in the EL layer 320.

In the present invention, light emitted from the light-emitting element 330 is extracted to the outside from the electrode 318 side or the electrode 322 side. Therefore, one of the electrode 318 and the electrode 322 is formed of a light-transmitting substance.

Note that a plurality of EL layers 320 may be stacked between the electrode 318 and the electrode 322 as in a light-emitting element 331 illustrated in FIG. 22B. In the case where x (x is a natural number of 2 or more) layers are stacked, a charge generation layer 320a is preferably provided between a y-th EL layer 320 and a (y+1)-th EL layer 320. Note that y is a natural number greater than or equal to 1 and less than x.

The charge generation layer 320a can be formed using a composite material of an organic compound and a metal oxide, a metal oxide, a composite material of an organic compound and an alkali metal, an alkaline earth metal, or a compound thereof; alternatively, these materials can be combined as appropriate. Examples of the composite material of an organic compound and a metal oxide include composite materials of an organic compound and a metal oxide such as vanadium oxide, molybdenum oxide, and tungsten oxide. As the organic compound, various compounds can be used; for example, a low molecular compound such as an aromatic amine compound, a carbazole derivative, or aromatic hydrocarbon, or oligomer, dendrimer, polymer, or the like of the low molecular compound can be used. Note that the organic compound having hole mobility of 10⁻⁶ cm²/Vs or more is preferably used as a hole-transport organic compound. However, besides the above materials, others may be used as long as the material has a higher hole-transport property than an electron-transport property. These materials used for the charge generation layer 320a have excellent carrier-injection properties and carrier-transport properties; thus, the light-emitting element 330 can be driven with low current and with low voltage.

Note that the charge generation layer 320a may be formed with a combination of a composite material of an organic compound and a metal oxide and another material. For example, the charge generation layer 320a may be formed by a combination of a layer containing the composite material of an organic compound and a metal oxide with a layer containing one compound selected from among electron-donating substances and a compound having a high electron-transport property. Furthermore, the charge generation layer 320a may be formed by a combination of a layer containing the composite material of an organic compound and a metal oxide with a transparent conductive film.

The light-emitting element 331 having such a structure is unlikely to have problems such as energy transfer and quenching and has an expanded choice of materials, and thus can easily have both high emission efficiency and a long lifetime. Furthermore, a light-emitting element which provides phosphorescence from one of light-emitting layers and fluorescence from the other of the light-emitting layers can be easily obtained.

The charge generation layer 320a has a function of injecting holes to one of the EL layers 320 that is in contact with the charge generation layer 320a and a function of injecting electrons to the other EL layer 320 that is in contact with the charge generation layer 320a, when voltage is applied between the electrode 318 and the electrode 322.

The light-emitting element 331 illustrated in FIG. 22B can provide a variety of emission colors by changing the type of the light-emitting substance used for the EL layer 320. In addition, a plurality of light-emitting substances having different emission colors may be used as the light-emitting substances, whereby light emission having a broad spectrum or white light emission can be obtained.

In the case of obtaining white light emission using the light-emitting element 331 illustrated in FIG. 22B, as for the combination of a plurality of EL layers, a structure for emitting white light including red light, blue light, and green light may be used; for example, the structure may include a light-emitting layer containing a blue fluorescent substance as a light-emitting substance and a light-emitting layer containing green and red phosphorescent substances as light-emitting substances. Alternatively, a structure including a light-emitting layer emitting red light, a light-emitting layer emitting green light, and a light-emitting layer emitting blue light may be employed. Further alternatively, with a structure including light-emitting layers emitting light of complementary colors, white light emission can be obtained. In a stacked-layer element including two light-emitting layers in which light emitted from one of the light-emitting layers and light emitted from the other light-emitting layer have complementary colors to each other, the combinations of colors are as follows: blue and yellow, blue-green and red, and the like.

Note that in the structure of the above-described stacked-layer element, by providing the charge generation layer between the stacked light-emitting layers, the element can have long lifetime in a high-luminance region while keeping the current density low. In addition, a voltage drop due to the resistance of the electrode material can be reduced, whereby uniform light emission in a large area is possible.

This embodiment can be implemented in an appropriate combination with any of the structures described in the other embodiments.

### Embodiment 6

In this embodiment, an example of a lighting device or a display device including the light-emitting device of one embodiment of the present invention will be described with reference to drawings.

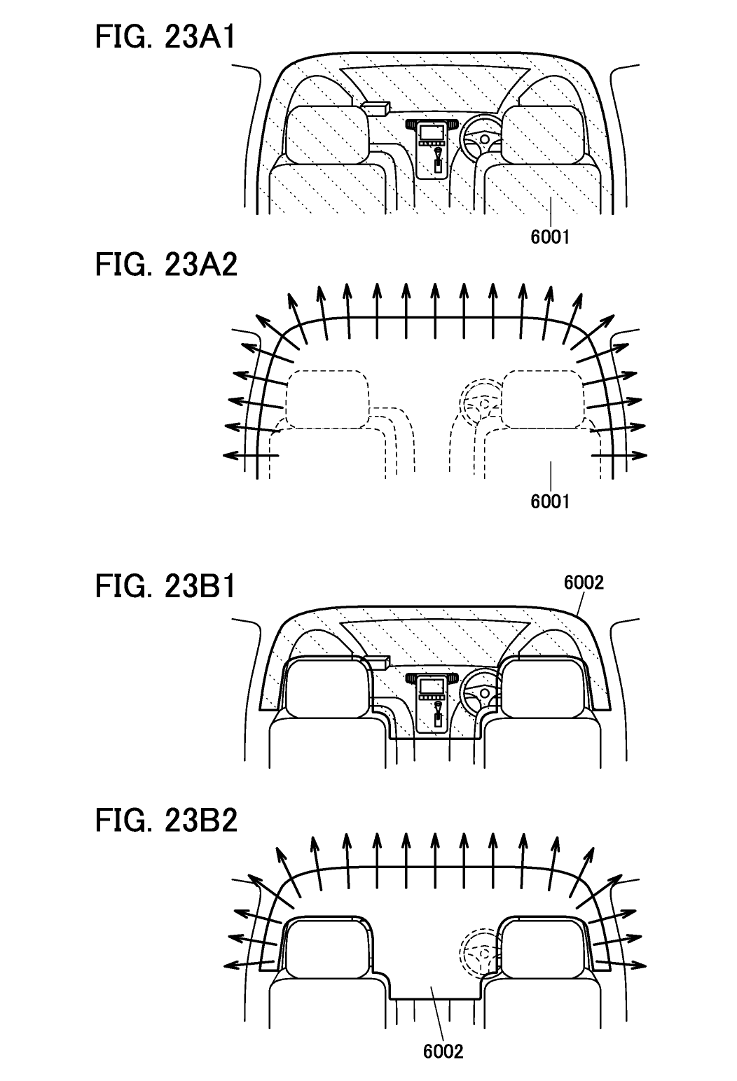

FIGS. 23A1 and 23B1 illustrate an example in which a lighting device 6001 or a lighting device 6002 to which the light-emitting device of one embodiment of the present invention is applied is provided between a front seat and a back seat of a taxi. In each of the lighting device 6001 and the lighting device 6002, the light-emitting device of one embodiment of the present invention is provided over an acrylic resin substrate or a glass substrate. Note that in the case where a glass substrate is used for the lighting device 6001 or the lighting device 6002, a transparent anti-dispersion film may be attached to prevent dispersion of the substrate when broken. Moreover, the light-emitting device of one embodiment of the present invention can also function as an anti-dispersion film.

FIG. 23A1 illustrates an example in which the size of the lighting device 6001 ranges around from the ceiling to the floor of the taxi. FIG. 23B1 illustrates an example in which the size of the lighting device 6002 ranges around from the ceiling to the upper half of the front seat of the taxi.

When light is not emitted from the lighting device 6001, the state ahead of the taxi can be seen through the lighting device 6001. On the other hand, when light is not emitted from the lighting device 6002, the state ahead of the taxi can be seen through the lighting device 6002.

If the taxi is attacked by a robber or the like, the rubber or the like can be threatened by light emitted from the lighting device 6001 or the lighting device 6002. Furthermore, the rubber or the like can be confined in the back seat with light emitted from the lighting device 6001 or the lighting device 6002; therefore, the number of solved crimes can be increased.

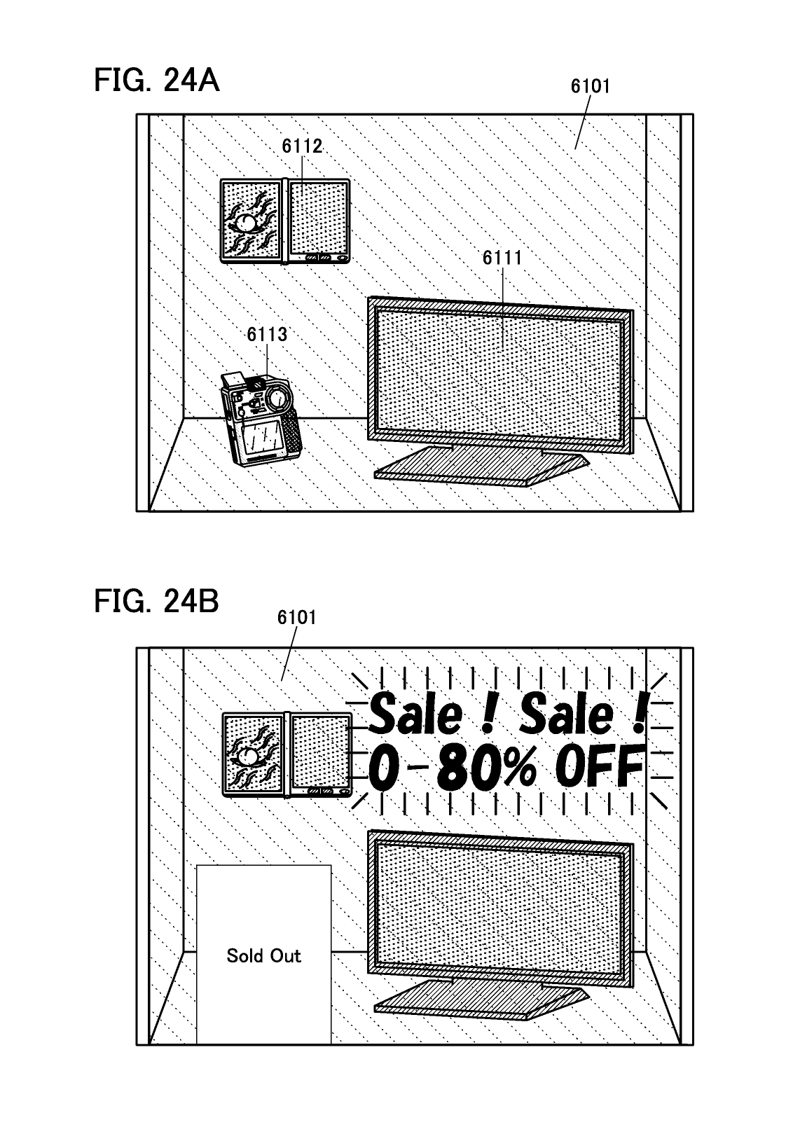

FIG. 24A illustrates an example in which the light-emitting device of one embodiment of the present invention is applied to a show window 6101 of products. A television 6111, a portable information terminal 6112, and a digital still camera 6113 are shown on the back of the show window 6101.

As illustrated in FIG. 24B, information such as characters or images can be displayed on the show window 6101. In addition, the conditions of the products shown at the back of the show window 6101 can be checked while information such as characters or images is displayed on the show window 6101. Moreover, light is emitted only from a given region of the show window 6101 using the light-emitting device of one embodiment of the present invention, so that the back of the region can be made less visible. Among a plurality of displayed products in FIG. 24B, only the digital still camera 6113 is made invisible.

This embodiment can be implemented in an appropriate combination with any of the structures described in the other embodiments.

This application is based on Japanese Patent Application serial No. 2013-190321 filed with the Japan Patent Office on Sep. 13, 2013, the entire contents of which are hereby incorporated by reference.

1. A light-emitting device comprising:
a light-emitting portion; and
a plurality of light-transmitting portions,
wherein the light-emitting portion comprises a net-like shape.

2. The light-emitting device according to claim 1,
wherein the light-emitting portion and the plurality of light-transmitting portions are over one side of a substrate,
wherein light from the one side of the substrate is transmitted to an opposite side of the substrate through the plurality of light-transmitting portions, and
wherein the light-emitting portion emits light to the opposite side of the substrate.

3. The light-emitting device according to claim 1,
wherein the light-emitting portion comprises a light-emitting element, and
wherein the light-emitting element is an organic EL element.

4. The light-emitting device according to claim 1,
wherein the light-emitting portion comprises a light-emitting element, and
wherein the light-emitting element comprises a transistor.

5. The light-emitting device according to claim 4,
wherein an oxide semiconductor is used for a semiconductor layer of the transistor where a channel is formed.

6. The light-emitting device according to claim 1, wherein the light-emitting device is flexible.

7. The light-emitting device according to claim 1, wherein the light-emitting device has a bottom-emission structure.

8. The light-emitting device according to claim 1, wherein the light-emitting device has a top-emission structure.

9. The light-emitting device according to claim 1, wherein the light-emitting device has a dual-emission structure.

10. A lighting device comprising the light-emitting device according to claim 1.

11. A display device comprising the light-emitting device according to claim 1.

12. A light-emitting device comprising:
a plurality of light-emitting portions; and
a light-transmitting portion,
wherein the plurality of light-emitting portions are arranged in a matrix, and
wherein the light-transmitting portion comprises a net-like shape.

13. The light-emitting device according to claim 12,
wherein the plurality of light-emitting portions and the light-transmitting portion are over one side of a substrate,
wherein light from the one side of the substrate is transmitted to an opposite side of the substrate through the light-transmitting portion, and
wherein the plurality of light-emitting portions emit light to the opposite side of the substrate.

14. The light-emitting device according to claim 12,
wherein the plurality of light-emitting portions each comprise a light-emitting element, and
wherein the light-emitting element is an organic EL element.

15. The light-emitting device according to claim 12,
wherein the plurality of light-emitting portions each comprise a light-emitting element, and
wherein the light-emitting element comprises a transistor.

16. The light-emitting device according to claim 15, wherein an oxide semiconductor is used for a semiconductor layer of the transistor where a channel is formed.

17. The light-emitting device according to claim 12, wherein the light-emitting device is flexible.

18. The light-emitting device according to claim 12, wherein the light-emitting device has a bottom-emission structure.

19. The light-emitting device according to claim 12, wherein the light-emitting device has a top-emission structure.

20. The light-emitting device according to claim 12, wherein the light-emitting device has a dual-emission structure.

21. A lighting device comprising the light-emitting device according to claim 12.

22. A display device comprising the light-emitting device according to claim 12.
